(19) United States
(12) Patent Application Publication
(10) Pub. No.: US 2018/0204704 A1
(43) Pub. Date: Jul. 19, 2018

(54) CHARGED PARTICLE BEAM APPARATUS

(71) Applicant: HITACHI HIGH-TECH SCIENCE CORPORATION, Tokyo (JP)

(72) Inventors: Masato SUZUKI, Tokyo (JP); Satoshi TOMIMATSU, Tokyo (JP); Makoto SATO, Tokyo (JP)

(21) Appl. No.: 15/871,753

(22) Filed: Jan. 15, 2018

(30) Foreign Application Priority Data
Jan. 19, 2017 (JP) 2017-007354

(51) Int. Cl. H01J 37/20; H01J 37/28; G01N 23/2204; H01J 37/302; H01J 37/22

(52) U.S. Cl. CPC H01J 37/20; H01J 37/28; G01N 23/2204; H01J 2237/2817; H01J 37/222; G01N 2223/418; H01J 2237/31745; H01J 37/3023

(57) ABSTRACT

Disclosed is a charged particle beam apparatus for automatically preparing a sample piece from a sample. The apparatus includes a charged particle beam irradiation optical system that irradiates a charged particle beam, a sample stage that moves with the sample placed thereon, a sample piece transferring device that holds and transports the sample piece separated and extracted from the sample, a holder fixing base that holds a sample piece holder to which the sample piece is transferred, and a computer that performs control of destroying the sample piece held by the sample piece transferring device when an abnormality occurs after the sample piece transferring device holds the sample piece.

### CROSS REFERENCE TO RELATED APPLICATION

This application claims the benefit of Japanese Patent Application No. 2017-007354, filed Jan. 19, 2017, which is hereby incorporated by reference in its entirety into this application.

### BACKGROUND OF THE INVENTION

### 1. Technical Field

The present invention generally relates to a charge particle beam apparatus.

### 2. Description of the Related Art

There is a known conventional apparatus that extracts a sample piece by irradiating a sample with a charged particle beam composed of electrons or ions and which processes the sample piece into a shape suitable for various processes such as observation, analysis, and measurement by a scanning electron microscope (SEM) or a transmission electron microscope (TEM) (for example, refer to Patent Documents 1 and 2).

### DOCUMENTS OF RELATED ART

### Patent Document

(Patent Document 1) Japanese Patent Application Publication No. H5-052721

(Patent Document 2) Japanese Patent Application Publication No. 2008-153239

### SUMMARY OF THE INVENTION

In the present specification, the term ‘sampling’ refers to a process of extracting a sample piece by irradiating a sample with a charged particle beam and processing the sample piece to have a suitable form for various processes such as observation, analysis, and measurement, and, more specifically, refers to a process of transferring a sample piece prepared by irradiating a sample with a focused ion beam (FIB) to a sample piece holder.

To data, a technology for automatically sampling sample pieces has not been sufficiently established.

A cause of obstructing automatic and continuous sampling is that when an abnormality occurs during image recognition processing executed for transferring a sample piece to a sample piece holder after extracting the sample piece using a needle, which is used for extracting and transporting a sample piece, the transition to the next process is interrupted.

For example, when determining whether a shape of a columnar portion of the sample piece holder to receive the sample piece transferred thereto is normal or abnormal from an image, when it is difficult to extract an edge (outline) of the columnar portion, the image recognition processing is interrupted. Furthermore, for example, when it is difficult to normally perform template matching of the columnar portion due to deformation, damage, or a defect of the columnar portion, transition to the next process of transferring the sample piece is interrupted. This situation obstructs repetitive automatic continuous sampling that is originally intended.

The present invention has been made in view of the above problems, and an objective of the present invention is to provide a charge particle beam apparatus capable of automatically performing an operation of extracting a sample piece formed by processing a sample with an ion beam and of transferring the sample piece to a sample piece holder.

(1) According to one aspect of the present invention, there is provided a charged particle beam apparatus for automatically preparing a sample piece from a sample, the charged particle beam apparatus including: a charged particle beam irradiation optical system configured to irradiate a charged particle beam; a sample stage configured to move with the sample placed thereon; a sample piece transferring device configured to hold and transport the sample piece separated and extracted from the sample; a holder fixing base configured to hold a sample piece holder to which the sample piece is to be transferred; and a computer configured to perform control of destroying the sample piece held by the sample piece transferring device when an abnormality occurs after the sample piece transferring device holds the sample piece.

(2) In addition, according to one aspect of the present invention, in the charged particle beam apparatus described in (1), the computer may destroy the sample piece by irradiating the sample piece held by the sample piece transferring device with the charged particle beam.

(3) In addition, according to one aspect of the present invention, in the charged particle beam apparatus described in (2), the sample piece transferring device includes a needle configured to hold and transport the sample piece separated and extracted from the sample and a needle driving mechanism configured to drive the needle, and the computer sets a plurality of limited fields of view for limiting a region to which the charged particle beam is irradiated when destroying the sample piece, sequentially switches the limited fields of view in order from a limited field of view set at a region relatively far from the needle to a limited field of view set at a region relatively close to the needle, and controls the charged particle beam irradiation optical system and the needling driving mechanism such that the charged particle beam is irradiated to a region corresponding to the switched limited field of view.

(4) In addition, according to one aspect of the present invention, in the charged particle beam apparatus described in (3), the computer sets the limited fields of view such that a size of a limited field of view set at a region relatively close to the needle, among the plurality of limited fields of view, is smaller than a size of a limited field of view set at a region relatively far from the needle, and the computer sets the limited fields of view such that an intensity of the charged particle beam for the limited field of view set at the region relatively close to the needle, among the plurality of limited fields of view, is weaker than an intensity of the charged particle beam for the limited field of view set at the region relatively far from the needle.

(5) In addition, according to one aspect of the present invention, in the charged particle beam apparatus described in (4), the computer sets the plurality of limited fields of view such that the needle does not exist, based on a reference position of the sample piece obtained from an image formed by irradiating the sample piece with the charged particle beam and based on a size of the sample piece obtained from the image or known information.

(6) In addition, according to one aspect of the present invention, in the charged particle beam apparatus described in (5), the computer drives the needle driving mechanism such that the reference position of the sample piece acquired from the image formed by irradiating the sample piece with the charged particle beam coincides with a center of a field of view of the charged particle beam, when destroying the sample piece.

(7) In addition, according to one aspect of the present invention, in the charged particle beam apparatus described in (6), the computer sets a position of an edge at a first of the sample piece, which is opposite to a second end to which the needle is connected, when viewed from a center of the sample piece, as the reference position of the sample piece.

(8) In addition, according to one aspect of the present invention, in the charged particle beam apparatus described in (1), the sample piece transferring device includes a needle configured to hold and transport the sample piece separated and extracted from the sample and a needle driving mechanism configured to drive the needle, and the computer controls the needle driving mechanism such that the sample piece held by the needle collides with an obstacle, whereby the sample piece is destroyed.

As described above, according to the present invention, since the charged particle beam apparatus destroys the sample piece held by the sample piece transferring device when an abnormality occurs, operation of the charged particle beam apparatus can proceed to the next process, for example, to a process of sampling a new sample piece. Therefore, it is possible to automatically and continuously perform the sampling operation of extracting a sample piece formed by processing a sample with an ion beam and transferring the sample piece to the sample piece holder.

### BRIEF DESCRIPTION OF THE DRAWINGS

FIG. 1 is a diagram illustrating the construction of a charged particle beam apparatus according to one embodiment of the present invention;

FIG. 2 is a plan view illustrating a sample piece before being extracted from a sample in the charged particle beam apparatus according to the embodiment of the present invention;

FIG. 3 is a plan view illustrating a sample piece holder of the charged particle beam device according to the embodiment of the present invention;

FIG. 4 is a side view illustrating the sample piece holder of the charged particle beam apparatus according to the embodiment of the present invention;

FIG. 5 is a flowchart illustrating the operation of the charged particle beam apparatus according to the embodiment of the present invention and illustrating, particularly, an initial setting process;

FIGS. 6a and 6b are schematic diagrams used to describe the tip (true tip) of a needle repeatedly used in the charged particle beam apparatus according to the embodiment of the present invention, in which FIG. 6a is a schematic diagram illustrating the true tip of the needle and FIG. 6b is a schematic diagram illustrating a first image obtained based on an absorption current signal;

FIGS. 7a and 7b are schematic diagrams of a secondary electron image formed by an electron beam irradiated from the tip of the needle of the charged particle beam apparatus according to the embodiment of the present invention, in which FIG. 7a is a schematic diagram illustrating a second image acquired by extracting a brighter region than the background from an image and FIG. 7b is a schematic diagram illustrating a third image acquired by extracting a darker region than the background;

FIG. 8 is a schematic diagram illustrating a fourth image synthesized from the second image and the third image illustrated in FIGS. 7a and 7b;

FIG. 9 is a flowchart illustrating the operation of the charged particle beam apparatus according to the embodiment of the present invention and illustrating, particularly, a sample piece pickup process;

FIG. 10 is a schematic diagram illustrating a position at which the needle stops moving when the needle of the charged particle beam apparatus according to the embodiment of the present invention is connected to a sample piece;

FIG. 11 is a diagram illustrating the tip of the needle and a sample piece in an image formed by a focused ion beam irradiated by the charged particle beam apparatus according to the embodiment of the present invention;

FIG. 12 is a diagram illustrating the tip of the needle and a sample piece in an image formed by an electron beam irradiated by the charged particle beam apparatus according to the embodiment of the present invention;

FIG. 13 is a diagram illustrating a processing range including a connection processing position at which the needle and a sample piece are connected with each other, within an image formed by a focused ion beam irradiated by the charged particle beam apparatus according to the embodiment of the present invention;

FIG. 14 is a schematic diagram illustrating a positional relationship between the needle and a sample piece in the charged particle beam apparatus according to the embodiment of the present invention when the sample piece is connected to the needle;

FIG. 15 is a diagram illustrating a cutting position T1 in a sample and a support portion of a sample piece, which is shown in an image formed by a focused ion beam irradiated by the charged particle beam apparatus according to the embodiment of the present invention;

FIG. 16 is a diagram illustrating a state in which the needle connected to a sample piece is evacuated, in an image formed by an electron beam irradiated by the charged particle beam apparatus according to the embodiment of the present invention;

FIG. 17 is a diagram illustrating a state in which a stage is evacuated (moved away) from the needle connected to a sample piece, in an image formed by an electron beam irradiated by the charged particle beam apparatus according to the embodiment of the present invention;

FIG. 18 is a diagram illustrating a sample piece attachment position on a columnar portion in an image formed by a focused ion beam irradiated by the charged particle beam apparatus according to the embodiment of the present invention;

FIG. 19 is a diagram illustrating a sample piece attachment position on a columnar portion in an image formed by an electron beam irradiated by the charged particle beam apparatus according to the embodiment of the present invention;

FIG. 20 is a flowchart illustrating the operation of the charged particle beam apparatus according to the embodiment of the present invention and illustrating more particularly a sample piece mounting process;

FIG. 21 is a diagram illustrating the needle that has stopped moving to stay around a sample piece attachment position on a sample base, in an image formed by a focused ion beam irradiated by the charged particle beam apparatus according to the embodiment of the present invention;

FIG. 22 is a diagram illustrating the needle that has stopped moving to stay around a sample piece attachment position on a sample base, in an image formed by an electron beam irradiated by the charged particle beam apparatus according to the embodiment of the present invention;

FIG. 23 is a diagram illustrating a processing range when a sample piece connected to the needle is connected to a sample base, in an image formed by a focused ion beam irradiated by the charged particle beam apparatus according to the embodiment of the present invention;

FIG. 24 is a diagram illustrating a cutting position at which a deposition film that connects a needle and a sample piece with each other is cut in an image formed by a focused ion beam irradiated by the charged particle beam apparatus according to the embodiment of the present invention;

FIG. 25 is a diagram illustrating a state in which the needle is evacuated, in image data formed by a focused ion beam irradiated by the charged particle beam apparatus according to the embodiment of the present invention;

FIG. 26 is a diagram illustrating a state in which the needle is evacuated, in an image formed by an electron beam irradiated by the charged particle beam apparatus according to the embodiment of the present invention;

FIG. 27 is a flowchart illustrating the operation of the charged particle beam apparatus according to the embodiment of the present invention and illustrating particularly an error processing process;

FIG. 28 is a diagram illustrating an edge of a sample piece connected to the needle, the edge being extracted from an absorption current image formed by a focused ion beam irradiated by the charged particle beam apparatus according to the embodiment of the present invention.

FIG. 29 is a diagram illustrating an edge of a sample piece connected to the needle, the edge being extracted from an absorption current image formed by a focused ion beam irradiated by the charged particle beam apparatus according to the embodiment of the present invention, and a center position of a field of view of the focused ion beam;

FIG. 30 is a diagram illustrating an edge of a sample piece connected to the needle, the edge being extracted from an secondary electron image formed by an electron beam irradiated by the charged particle beam apparatus according to the embodiment of the present invention, and a center position of a field of view of the electron beam;

FIG. 31 is a diagram illustrating a first limited field of view in an image formed by a focused ion beam irradiated by the charged particle beam apparatus according to the embodiment of the present invention;

FIG. 32 is a diagram illustrating a second limited field of view in an image formed by a focused ion beam irradiated by the charged particle beam apparatus according to the embodiment of the present invention;

FIG. 33 is a diagram illustrating an example of a state in which a residue of a deposition film remains at the tip of the needle after a sample piece is destroyed by a focused ion beam irradiated thereto, in an image formed by a focused ion beam irradiated by the charged particle beam apparatus according to the embodiment of the present invention;

FIG. 34 is a diagram illustrating state in which no residue of a deposition film remains at the tip of the needle after a sample piece is destroyed by a focused ion beam irradiated thereto, in an image formed by a focused ion beam irradiated by the charged particle beam apparatus according to the embodiment of the present invention;

FIG. 35 is an explanatory view illustrating a positional relationship between a columnar portion and a sample piece, based on an image formed by a focused ion beam irradiated by the charged particle beam apparatus according to the embodiment of the present invention;

FIG. 36 is an explanatory view illustrating a positional relationship between a columnar portion and a sample piece, based on an image formed by an electron beam irradiated by the charged particle beam apparatus according to the embodiment of the present invention;

FIG. 37 is an explanatory view illustrating templates created by using edges of a sample piece and a columnar portion, based on an image formed by an electron beam irradiated by the charged particle beam apparatus according to the embodiment of the present invention;

FIG. 38 is an explanatory view illustrating templates showing a positional relationship between a columnar portion and a sample piece when the columnar portion and the sample piece are connected, in the charged particle beam apparatus according to the embodiment of the present invention;

FIG. 39 is a diagram illustrating an approach mode state at a rotation angle of 0° of the needle to which a sample piece is connected, in image data formed by a focused ion beam irradiated by the charged particle beam apparatus according to the embodiment of the present invention;

FIG. 40 is a diagram illustrating an approach mode state at a rotation angle of 0° of the needle to which a sample piece is connected, in an image formed by an electron beam irradiated by the charged particle beam apparatus according to the embodiment of the present invention;

FIG. 41 is a diagram illustrating an approach mode state at a rotation angle of 90° of the needle to which a sample piece is connected, in an image formed by a focused ion beam irradiated by the charged particle beam apparatus according to the embodiment of the present invention;

FIG. 42 is a diagram illustrating an approach mode state at a rotation angle of 90° of the needle to which a sample piece is connected, in an image formed by an electron beam irradiated by the charged particle beam apparatus according to the embodiment of the present invention;

FIG. 43 is a diagram illustrating an approach mode state at a rotation angle of 180° of the needle to which a sample piece is connected, in an image formed by a focused ion beam irradiated by the charged particle beam apparatus according to the embodiment of the present invention;

FIG. 44 is a diagram illustrating an approach mode state at a rotation angle of 180° of the needle to which a sample piece is connected, in an image formed by an electron beam irradiated by the charged particle beam apparatus according to the embodiment of the present invention;

FIG. 45 is an explanatory view for describing preparation of a planar sample piece according to one embodiment of the present invention, and is a diagram illustrating an approach mode state at a rotation angle of 90° of the needle to which a sample piece is connected, on in image formed by a focused ion beam irradiated by the charged particle beam apparatus according to the present invention;

FIG. 46 is an explanatory view for describing preparation of a planar sample piece according to one embodiment of the present invention, and is a diagram illustrating a state in which a separated sample piece comes into contact with a sample piece holder; and

FIG. 47 is an explanatory view for describing preparation of a planar sample piece according to one embodiment of the present invention, and is a diagram illustrating a state in which a planar sample piece can be prepared by lamellating a sample piece fixed to a sample holder.

### DESCRIPTION OF THE PREFERRED EMBODIMENTS

Hereinafter, a charged particle beam apparatus capable of automatically preparing a sample piece, according to one embodiment of the present invention, will be described with reference to the accompanying drawings.

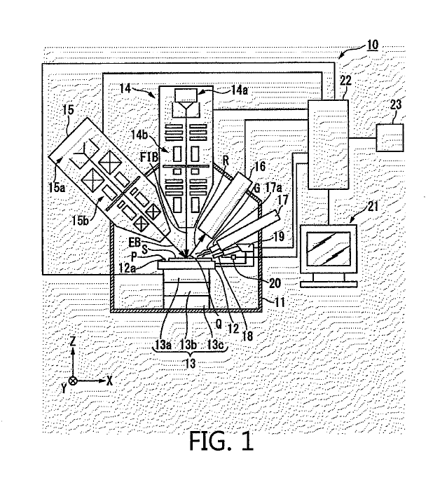

FIG. 1 is a diagram illustrating the construction of a charged particle beam apparatus 10 according to one embodiment of the present invention. As illustrated in FIG. 1, the charged particle beam apparatus 10 according to the embodiment of the present invention includes a sample chamber 11 that can maintain the inside of the charged particle beam apparatus in a vacuum state, a stage 12 that can fix a sample S and a sample piece holder P inside the sample chamber 11, and a stage driving mechanism 13 that drives the stage 12. The charged particle beam apparatus 10 is equipped with a focused ion beam irradiation optical system 14 that irradiates an irradiation target disposed within a predetermined irradiation region (i.e. scanning range) in the sample chamber 11, with a focused ion beam (FIB). The charged particle beam apparatus 10 is provided with an electron beam irradiation optical system 15 that irradiates an irradiation target disposed within a predetermined irradiation region in the sample chamber 11, with an electron beam (EB). The charged particle beam apparatus 10 is equipped with a detector 16 that detects secondary charged particles (secondary electrons, secondary ions, or the like) R generated from the irradiation target due to irradiation of a focused ion beam or an electron beam thereto. The charged particle beam apparatus 10 is equipped with a gas supply unit 17 that supplies gas G to the surface of the irradiation target. The gas supply unit 17 is specifically a nozzle 17a having an outer diameter of about 200 μm. The charged particle beam apparatus 10 includes: a needle 18 that extracts a fine sample piece Q from the sample S fixed to the stage 12, holds the sample piece Q, and transfers the sample piece Q to the sample piece holder P; a needle driving mechanism 19 that drives the needle 18 to transport the sample piece Q; and an absorption current detector 20 that detects an inflow current (also referred to as an absorption current) of a charged particle beam. A signal of the inflow current is transmitted to a computer 22 so as to be imaged.

The needle 18 and the needle driving mechanism 19 are collectively referred to as a sample piece transferring device. The charged particle beam apparatus 10 is provided with a display device 21 that displays image data or the like based on the secondary charged particles R detected by the detector 16, the computer 22, and an input device 23.

The irradiation targets of the focused ion beam irradiation optical system 14 and the electron beam irradiation optical system 15 are the sample S fixed to the stage 12, the sample piece Q, and the sample piece holder P or the needle 18 staying in an irradiation region.

The charged particle beam apparatus 10 according to the embodiment can perform various processes (etching, trimming, or the like) through imaging or sputtering of an irradiation target and form a deposition film or the like by irradiating the surface of the irradiation target with a focused ion beam. The charged particle beam apparatus 10 can perform a process of forming a sample piece Q (for example, a lamella, a needle-like sample, or the like) for transmission observation by a transmission electron microscope (TEM) or forming an analysis sample piece for analysis using an electron beam, from a sample S. The charged particle beam apparatus 10 can perform a process of transforming a sample piece Q transferred to a sample piece holder P into a thin film having a desired thickness (for example, 5 to 100 nm, etc.) suitable for transmission observation by a transmission electron microscope. The charged particle beam apparatus 10 can perform a process of observing the surface of an irradiation target by irradiating the surface of the irradiation target such as the sample piece Q and the needle 18 with a focused ion beam or an electron beam while scanning the irradiation target with the focused ion beam or the electron beam.

The absorption current detector 20 includes a preamplifier to amplify the inflow current flowing into the needle and transmits the amplified inflow current to the computer 22. A needle-shaped absorption current image can be displayed on the display device 21, based on the inflow current flowing into the needle and detected by the absorption current detector 20 and a signal synchronized with the scanning of the charged particle beam so that the shape of the needle and the position of the tip of the needle can be specified.

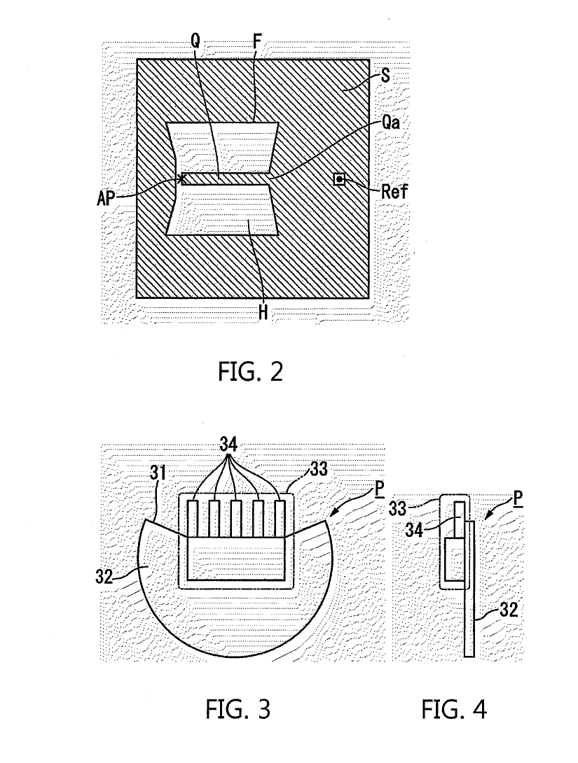

FIG. 2 is a plan view illustrating a sample piece Q that is formed by a focused ion beam irradiated to the surface of a sample S (hatched portion) and which is not yet extracted from the sample S, in the charged particle beam apparatus 10 according to the embodiment of the present invention. Reference symbol F denotes a processing range of a focused ion beam, i.e., a scanning range of a focused ion beam, and a portion (white portion) inside the processing range is a processing region H which is sputtered by the focused ion beam and thus etched. Reference symbol Ref denotes a reference mark (reference point) indicating a position at which the sample piece Q is formed (i.e. a portion not etched but left). For example, the reference mark (reference point) Ref is a fine hole of 30 nm that is formed in a deposition film (for example, a square hole being 1 μm long at each side thereof) by a focused ion beam and which can be easily recognized due to its high contrast in an image formed by a focused ion beam or an electron beam. The deposition film is used for coarse detection of the position of the sample piece Q, and the fine hole is used for finely controlled positioning. In the sample S, most of the periphery of a sample piece Q, at both sides and a lower end of the sample piece Q, is etched away but a support portion Qa connected to the sample S remains. The sample piece Q is cantilevered to the sample S by the support portion Qa. The sample piece Q is a minute sample piece having a length (dimension in the longitudinal direction) of, for example, about 10 μm, 15 μm, or 20 μm, and a width (thickness) of about 500 nm, 1 μm, 2 μm, or 3 μm.

The sample chamber 11 is constructed such that the interior thereof can be vacuumed to a desired vacuum state by an air exhauster (not shown) and can be maintained at the desired vacuum state.

The stage 12 holds the sample S. The stage 12 includes a holder fixing base 12a that holds the sample piece holder P. The holder fixing base 12a may have a structure capable of supporting a plurality of sample piece holders P mounted thereon.

FIG. 3 is a plan view of the sample piece holder P and FIG. 4 is a side view of the sample piece holder P. The sample piece holder P includes a substantially semicircular plate-like base portion 32 having a cutout portion 31, and a sample base 33 fixed to the cutout portion 31. The base portion 32 is made of, for example, metal in the form of a circular plate having a diameter of 3 mm and a thickness of 50 μm. The sample base 33 is formed from, for example, a silicon wafer through a semiconductor manufacturing process, and is attached to the cutout portion 31 via a conductive adhesive. The sample base 33 has a comb shape with a plurality of (for example, five, ten, fifteen, twenty, etc.) teeth that are protrusions arranged to be spaced from each other. The sample base 33 has a plurality of columnar portions (hereinafter also referred to as pillars) 34 to which the sample pieces Q are to be transferred.

The columnar portions 34 have respectively different widths. Images of the sample pieces Q transferred to the respective columnar portions 34 and images of the columnar portions 34 are respectively associated with each other, and are stored in the computer 22 in association with the corresponding sample piece holders P. Therefore, even when a large number of sample pieces Q are produced from one sample S, the sample pieces Q can be recognized without fail. Furthermore, an analysis target sample piece Q to undergo a subsequent analysis process using a transmission electron microscope (TEM) or the like can be precisely matched with the exact position in the sample S, at which the analysis target sample piece Q is picked from the sample S. Each columnar portion 34 has a tip portion having a thickness of 10 μm or less or a thickness of 5 μm or less, and holds the sample piece Q attached to the tip portion.

The base portion 32 is not limited to the circular plate shape having a diameter of 3 mm and a thickness of 50 μm as described above, but may be a rectangular plate shape having a length of 5 mm, a height of 2 mm, a thickness of 50 μm. That is, the shape of the base portion 32 may be a shape that can be mounted on the stage 12 to be introduced into a transmission electron microscope in a subsequent process, or a shape by which all of the sample pieces Q mounted on the sample base 33 can be disposed within a movable range of the stage 12. When the base portion 32 has the shape described above, all the sample pieces Q mounted on the sample base 33 can be observed with a transmission electron microscope (TEM).

The stage driving mechanism 13 is housed inside the sample chamber 11 in a state of being connected to the stage 12, and moves the stage 12 along a predetermined axis in accordance with a control signal output from the computer 22. The stage driving mechanism 13 includes a moving mechanism 13a that moves the stage 12 in parallel with along at least X and Y axes that are in parallel with a horizontal plane and are orthogonal to each other and in parallel with along with a Z axis orthogonal to each of the X and Y axes. The stage driving mechanism 13 includes a tiling mechanism 13b that tilts the stage 12 about the X axis or the Y axis and a rotating mechanism 13c that rotates the stage 12 about the Z axis.

The focused ion beam irradiation optical system 14 is fixed to the sample chamber 11 in a state in which a beam emission portion (not shown) thereof is disposed inside the sample chamber 11 and is arranged to face the stage 12 disposed within an irradiation region, directly from above the stage 12, and in which an optical axis thereof is in parallel with a vertical direction. Thereby, it is possible to irradiate the irradiation targets such as the sample S placed on the stage 12, the sample piece Q, and the needle 18 staying within the irradiation region, with a focused ion beam irradiated downward in the vertical direction, i.e., irradiated from directly above the irradiation targets. Further, the charged particle beam apparatus 10 may be equipped with a different ion beam irradiation optical system instead of the focused ion beam irradiation optical system 14 described above. The ion beam irradiation optical system is not limited to an optical system that generates a focused beam. The ion beam irradiation optical system may be, for example, a projection type ion beam irradiation optical system that is equipped with a stencil mask having a standard opening and being disposed in an optical system and which forms a shaped beam having a shape the same as that of the opening of the stencil mask. With the use of the projection type ion beam irradiation optical system, it is possible to accurately form a shaped beam having a shape corresponding to a processing region around a sample piece Q and to shorten a processing time.

The focused ion beam irradiation optical system 14 includes an ion source 14a that generates ions and an ion optical system 14b that focuses and deflects the ions emitted from the ion source 14a. The ion source 14a and the ion optical system 14b are controlled in accordance with a control signal output from the computer 22. Further, irradiation positions, irradiation conditions, etc. of a focused ion beam are controlled by the computer 22. The ion source 14a is, for example, a liquid metal ion source or a plasma type ion source, which uses liquid gallium or the like, a field ionization type gas ion source, or the like. The ion optical system 14b includes, for example, a first electrostatic lens such as a condenser lens, an electrostatic deflector, a second electrostatic lens such as an objective lens, and the like. In the case where a plasma type ion source is used as the ion source 14a, it is possible to realize high processing speed by using a large current beam. Therefore, a plasma type ion source is suitable for sampling a sample piece from a large sample S.

The electron beam irradiation optical system 15 is fixed to the sample chamber 11 in a state in which a beam emission portion (not shown) thereof is disposed inside the sample chamber 11 and is oriented toward the stage 12 disposed within an irradiation region while being inclined at a predetermined angle (for example, 60°) with respect to the vertical direction, and in which an optical axis thereof is in parallel with the inclined direction. Thereby, it is possible to irradiate irradiation targets such as the sample S fixed to the state 12, the sample piece Q, and the needle 18 staying within the irradiation region, with an electron beam irradiated from obliquely above the irradiation targets.

The electron beam irradiation optical system 15 includes an electron source 15a that generates electrons and an electron optical system 15b that focuses and deflects the electrons emitted from the electron source 15a. The electron source 15a and the electron optical system 15b are controlled in accordance with a control signal output from the computer 22. Further, irradiation positions and irradiation conditions of the electron beam are controlled by the computer 22. The electron optical system 15b includes, for example, an electromagnetic lens, a deflector, and the like.

Alternatively, the positions of the electron beam irradiation optical system 15 and the focused ion beam irradiation optical system 14 may be switched so that the electron beam irradiation optical system 15 may be arranged in the vertical direction and the focused ion beam irradiation optical system 14 may be inclined at a predetermined angle with respect to the vertical direction.

The detector 16 detects the intensity (i.e., amount) of secondary charged particles (i.e., secondary electrons and secondary ions) R emitted from the irradiation targets such as the sample S, the needle 18, and the like when a focused ion beam or an electron beam is irradiated to the irradiation targets, and outputs information of the detected amount of the secondary charged particles R. The detector 16 is disposed at a position where the amount of the secondary charged particles R can be detected inside the sample chamber 11. For example, the detector 16 may be disposed at a position obliquely above the irradiation target such as the sample S disposed within the irradiation region, and is fixed to the sample chamber 11.

The gas supply unit 17 is fixed to the sample chamber 11, has a gas ejection unit (also referred to as a nozzle) disposed inside the sample chamber 11, and is arranged to face the stage 12. The gas supply unit 17 can supply the sample S with an etching gas that selectively promotes etching of the sample S when a focused ion beam is irradiated to the sample S, in accordance with the material of the sample S, or with a deposition gas that forms a deposition film of a metal or an insulator on the surface of the sample S. For example, when an etching gas such as xenon fluoride for etching a silicon-based sample S or water for etching an organic sample S is supplied to the sample S while a focused image beam is being irradiated to the sample S, an etching rate is material-selectively promoted. Further, for example, when a deposition gas containing platinum, carbon, tungsten or the like is supplied to the sample S while a focused ion beam is being irradiated to the sample S, a solid component decomposed from the deposition gas can be accumulated (deposited) on the surface of the sample S. Specific examples of the deposition gas include: carbon-containing gases such as phenanthrene, naphthalene, and pyrene; platinum-containing gases such as trimethyl.ethylcyclopentadienyl.platinum; and tungsten-containing gases such as tungsten hexacarbonyl. Depending on the supplied gas, it is also possible to perform etching or deposition with the supplied gas even in the case where an electron beam is irradiated to the sample S. However as the deposition gas used in the charged particle beam apparatus 10 of the present invention, a carbon-containing gas such as phenanthrene, naphthalene, or pyrene is most suitable in terms of deposition speed and reliable adhesion to the sample piece Q and the needle 18. Any one of those gases is preferably used.

The needle driving mechanism 19 is housed inside the sample chamber 11 in a state where the needle 18 is attached thereto, and displaces the needle 18 in accordance with a control signal output from the computer 22. The needle driving mechanism 19 is integrally provided with the stage 12, and thus moves in company with the stage 12, for example, when the stage 12 is rotated about a tilt axis (i.e., the X axis or the Y axis) by the tilting mechanism 13b. The needle driving mechanism 19 includes a moving mechanism (not shown) that moves the needle 18 in parallel with each of the three-dimensional coordinate axes and a rotating mechanism (not shown) that rotates the needle 18 about the central axis of the needle 18. Moreover, the three-dimensional coordinate axes are independent from a three-dimensional rectangular coordinate system of the sample stage 12. In a three-dimensional rectangular coordinate system with two-dimensional coordinate axes parallel to the surface of the stage 12, when the surface of the stage is in a tilted state or a rotated state, the coordinate system is tilted or rotated.

The computer 22 controls at least the stage driving mechanism 13, the focused ion beam irradiation optical system 14, the electron beam irradiation optical system 15, the gas supply unit 17, and the needle driving mechanism 19.

The computer 22 is disposed outside the sample chamber 11, and is connected with the display device 21 and the input device 23 such as a mouse or a keyboard which outputs a signal in accordance with the input of an operator.

The computer 22 controls the overall operation of the charged particle beam device 10 in accordance with a signal output from the input device 23 or a signal generated through a preset automatic operation control process or the like.

The computer 22 converts the detection amount of the secondary charged particles R detected by the detector 16 into a luminance signal associated with a corresponding irradiation position while scanning irradiation positions of a charged particle beam and generates image data indicating the shape of the irradiation target by using the two-dimensional distribution of the detection amounts. In absorption current image mode, the computer 22 detects an absorption current flowing into the needle 18 while scanning the irradiation positions of the charged particle beam, thereby generating absorption current image data indicating the shape of the needle 18 on the basis of the two-dimensional distribution (absorption current image) of the absorption current. The computer 22 causes the display device 21 to display screens for executing operations such as enlargement, reduction, movement, and rotation of each of image data as well as each of image data that is generated. The computer 22 causes the display device 21 to display a screen for various settings, such as mode selection and process settings, for automatic sequence control.

The charged particle beam apparatus 10 according to the embodiment of the present invention has the construction described above, and the operation of the charged particle beam apparatus 10 will be described below.

Hereinafter, the operation of automatic sampling performed by the computer 22, i.e., the operation of automatically transferring the sample piece Q formed by processing the sample S with the charged particle beam (focused ion beam) to the sample piece holder P will be sequentially described. The operation includes an initial setting process, a sample piece pickup process, and a sample piece mounting process.

<Initial Setting Process>

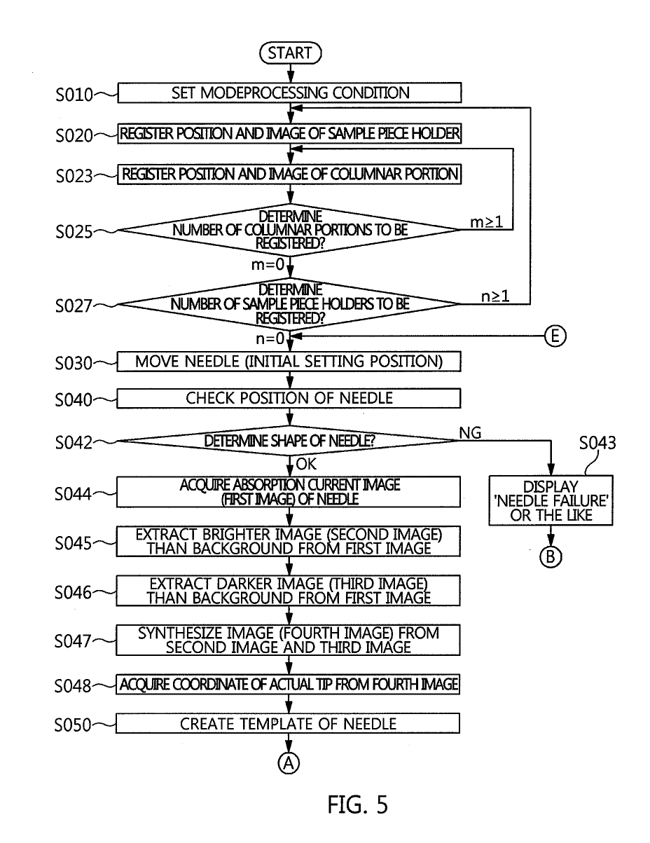

FIG. 5 is a flowchart illustrating the flow of an initial setting process of the automatic sampling operation performed by the charged particle beam apparatus 10 according to the embodiment of the present invention. First, at the start of the automatic sequence, the computer 22 performs a mode selection such as whether to perform a posture control mode to be described later, setting processing conditions (setting of processing positions, dimensions, number of items) and observation conditions for template matching, checking the shape of a needle tip, and the like in Step S010.

Next, the computer 22 creates a template of the columnar portion 34 in Step S020 to Step S027. In regards to the creation of the template, the computer 22 first performs position registration for the sample piece holder P installed on the holder fixing base 12a of the stage 12 on the basis of information input by an operator in Step S020. The computer 22 creates the template of the columnar portion 34 at the beginning of a sampling process. The computer 22 creates a template for each columnar portion 34. The computer 22 obtains stage coordinates of each columnar portion 34, creates a template of each columnar portion 34, then records the stage coordinates and the templates in association with each other, and uses the stored information when checking the shape of the columnar portion 34 through template matching (i.e., overlapping a template and an image). The computer 22 records in advance, for example, images themselves, edge information extracted from the images, and the like, as the templates of the columnar portions 34 used for template matching. The computer 22 can recognize the accurate position of the columnar portion 34 in a subsequent process, by performing template matching after moving the stage 12 and determining the shape of the columnar portion 34 by scores of the template matching. Using observation conditions such as contrast and magnification that are the same as those for template creation, as observation conditions for template matching, is desirable because accurate template matching can be performed thereby.

When multiple sample piece holders P are installed on the holder fixing base 12a and multiple columnar portions 34 are provided in each sample piece holder P, unique recognition code numbers for the respective sample piece holders P and unique recognition code numbers for the respective columnar portions 34 provided in each sample piece holder P may be predetermined, and the computer 22 may record the unique recognition code numbers in association with the coordinates and template information of the respective columnar portions 34.

Alternatively, the computer 22 also may record the coordinates of portions (extracted portions) at which the sample pieces Q are extracted from the sample S and image information of the surrounding sample surface in addition to the recognition code numbers, the coordinates of each columnar portion 34, and the template information of each columnar portion 34.

Alternatively, in the case of irregular samples such as rocks, ores, and biological samples, the computer 22 may record a low magnification wide visual field image, the position coordinates of the extracted portion, and the image as a set of information items and may record the information as recognition information. This recognition information may be stored in association with a lamellate sample S, or with a transmission electron microscope (TEM) image and the extracted position of the sample S.

The computer 22 performs position registration of the sample piece holders P prior to the movement of the sample pieces Q to be described later, thereby preliminarily confirming that the sample base 33 having a proper shape actually exists.

In the position registration processing, the computer 22 first causes the stage driving mechanism 13 to drive the stage 12 as a coarse adjustment operation, and aligns an irradiation region with a position at which the sample base 33 is attached to the sample piece holder P. Next, as a fine adjustment operation, the computer 22 extracts the positions of the multiple columnar portions 34 constituting the sample base 33 with the use of the templates created from design shapes (CAD information), from image data of each image formed through irradiation of charged particle beams (a focused ion beam and an electron beam). Then, the computer 22 registers (records) the extracted position coordinates and the images of the respective extracted columnar portions 34 as attachment positions of the sample pieces Q in Step S023. At this point, the images of the respective columnar portions 34 are compared with design drawings, CAD drawings, or the images of standard columnar portions 34, which are preliminarily prepared, to check deformation, defects, or missing of each columnar portion 34. When a certain columnar portion 34 is defective, the computer 22 records the position coordinates and the image of the defective columnar portion and information indicating that the columnar portion 34 is defective.

Next, it is determined whether there remains any columnar section 34 to be registered in the sample piece holder P that currently undergoes the registration processing in Step S025. When the determination result is “YES”, i.e., when the number of remaining columnar portions 34 to be registered is one or more, the processing is returned to Step S023 described above, and Step S023 and Step S025 are repeatedly performed until the number m of remaining columnar sections 34 to be further registered becomes zero. On the other hand, when the determination result is “NO”, that is, when the number m of remaining columnar sections 34 to be registered is zero, the processing proceeds to Step S027.

When a plurality of sample piece holders S is installed on the holder fixing base 12a, the position coordinates of the respective sample piece holders P and image data of the corresponding sample piece holders P are stored together with the code numbers of the respective sample piece holders P. In addition, the position coordinates of the respective columnar portions 34 in each sample piece holder P, the corresponding code numbers, and the image data thereof are also recorded (registered). The computer 22 may perform this position registration processing a predetermined number of times corresponding to the number of the sample pieces Q to be automatically sampled.

Next, the computer 22 determines whether there remains any sample piece holder P to be registered in Step S027. When the determination result is “YES”, that is, when the number of remaining sample piece holders P to be registered is one or more, the processing is returned to Step S020 described above, and Step S020 to Step S027 are repeatedly performed until the number of remaining sample piece holders P to be registered becomes zero. On the other hand, when the determination result is “NO”, that is, when the number n of remaining sample piece holders P to be registered is zero, the processing proceeds to Step S030.

Thereby, when several tens of sample pieces Q are automatically produced from one sample S, since the positions of multiple sample piece holders P are registered for each holder fixing base 12a and the positions of the respective columnar portions 34 are registered in the form of an image, it is possible to immediately draw a specific sample piece holder P to which the several tens of sample pieces Q are to be attached and a specific columnar portion 34 to a position within a field of view of a charged particle beam.

In addition, in the position registration processing (Step S020 and Step S023), when the sample piece holder P itself or the columnar portion 34 is deformed or broken and when the sample piece Q is not attached to the columnar portion, “unusable” (notation indicating that the sample piece Q is not attached) or the like is registered in association with the position coordinates, the image data, and the code number of the sample piece holder P or the columnar portion 34. As a result, the computer 22 can skip the sample piece holder P or the columnar portion 34 registered as being “unusable” at the time of transferring the sample piece Q described later and can move the next normal sample piece holder P or the next normal columnar portion 34 into the observation field of view.

Next, the computer 22 creates a template of the needle 18 in Step S030 to Step S050. The template is used for image matching when one accurately brings the needle (to be described later) close to the sample piece.

In the template creation process, first, the computer 22 causes the stage driving mechanism 13 to move the stage 12. Subsequently, the computer 22 causes the needle driving mechanism 19 to move the needle 18 to the initial setting position in Step S030. The initial setting position is a point (coincidence point) to which both of the focused ion beam and the electron beam can be irradiated and is a focal point on which both of the focused ion beam and the electron beam can be focused. Furthermore, the initial setting position is a predetermined position at which any complicated structure such as the sample S, which can be misrecognized as the needle, exists in the background in the image of the needle 18, after the preceding movement of the stage is performed. This coincidence point is a position where a same object can be observed at different angles through irradiation of a focused ion beam and an electron beam.

Next, the computer 22 recognizes the position of the needle 18 by using an absorption image mode in which an electron beam is irradiated in Step S040.

The computer 22 detects an absorption current flowing into the needle 18 by irradiating the needle 18 with an electron beam and generates absorption current image data. At this time, since the absorption current image has no background which can be misrecognized as the needle 18, the needle 18 can be recognized without being affected by the background image. The computer 22 acquires absorption current image data through irradiation of an electron beam. The reason why the template is formed by using the absorption current image is described below. When the needle approaches a sample piece, some shapes, such as a processed shape of the sample piece and a pattern formed on the surface of a sample, which can be misrecognized as the needle, are highly likely to exist in the background image of the needle. Therefore, there is a high risk of misrecognition in the case of using a secondary electron image. For this reason, an absorption current image that is not affected by the background image is used to prevent false recognition. Since a secondary electron image is susceptible to a background image and has a high risk of false recognition, a secondary electron image is not suitable as a template image. As such, since a carbon deposition film attached to the tip of the needle cannot be recognized from an absorption current image, it is difficult to recognize the actual tip of the needle. However, an absorption current image is suitable in terms of pattern matching with a template.

Next, the computer 22 determines the shape of the needle 18 in Step S042.

When a sample piece Q is not attached to the needle 18 due to any reason such as deformation or breakage of the tip of the needle 18 (Step S042; NG), the automatic sampling operation ends without performing Step S050 and subsequent steps. That is, when the shape of the tip of the needle is abnormal, the following steps are not performed but an operator replaces the defective needle with a new one. In the needle shape determination of Step S042, for example, when the tip of the needle is deviated by a distance of 100 μm or more, from a predetermined position within a field of view having a length of 200 μm at each side, the shape of the needle is determined as being abnormal. Further, when the shape of the needle is determined as being abnormal in Step S042, the message “needle failure” or the like is displayed on the display device 21 in Step S043, thereby warning an operator of the situation. The needle 18 determined as being defective may be replaced with a new one. However, when the defect of the needle 18 is minor, a focused ion beam may be irradiated to the tip of the needle 18 to reshape the needle 18.

In Step S042, when the needle 18 has a predetermined normal shape, the next step, Step S044, is performed.

Here, the state of the tip of the needle will be described.

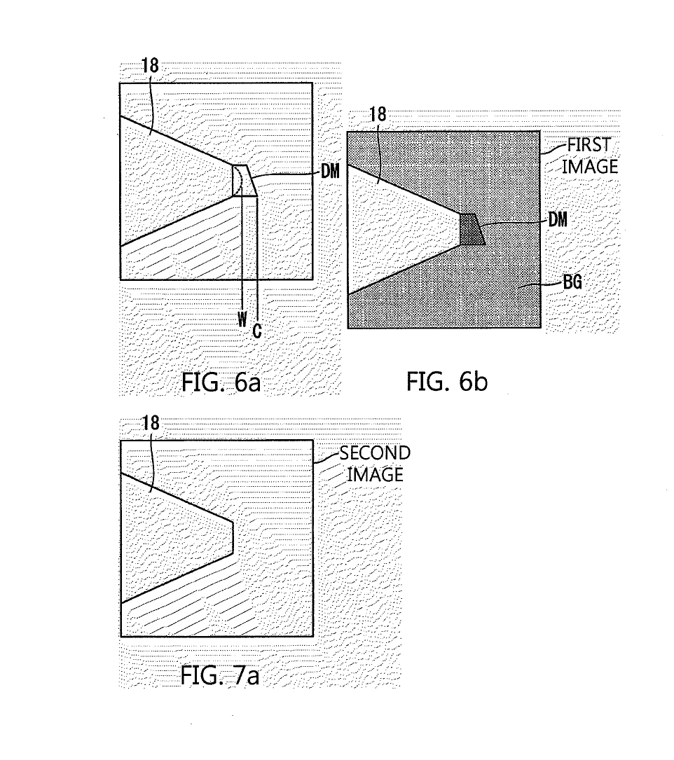

FIG. 6a is an enlarged schematic diagram of the tip of a needle for describing a state in which a residue of a carbon deposition film DM is attached to the tip of the needle 18 (tungsten needle). The tip of the needle 18 is managed not to be cut or deformed by a focused ion beam irradiated thereto so that the needle 18 can be repetitively used for a plurality of times of sampling. During multiple times of sampling, a residue of a carbon deposition film DM is likely to adhere to the tip of the needle 18 that is holding a sample piece Q. With samplings repeated, the residue of the carbon deposition film DM at the tip of the needle gradually increases to have a shape slightly protruding from the position of the tip of the tungsten needle. Therefore, the coordinates of the actual tip of the needle 18 are not the coordinates of the true tip W of the tungsten needle (original needle 18) but are the coordinates of the tip C of the residue of the carbon deposition film DM. The reason why a template is formed by using an absorption current image is described below. When the needle 18 approaches a sample piece Q, shapes, such as a processed shape of a sample piece Q and a pattern on the surface of a sample, which can be misrecognized as the needle 18, are highly likely to exist in the background image of the needle 18. Therefore, when a secondary electron image is used, there is a high risk of misrecognition. For this reason, an absorption current image that is not affected by the background image is used to prevent misrecognition. Since a secondary electron image is easily affected by a background image, a secondary electron image easily leads to misrecognition. Therefore, a secondary electron image is not suitable as a template image. As described above, since a carbon deposition film DM at the tip of the needle cannot be recognized on an absorption current image, it is difficult to find an actual needle tip from an absorption current image. However, an absorption current image is suitable for pattern matching with a template.

FIG. 6b is a schematic diagram of an absorption current image of a tip portion of a needle to which a carbon deposition film DM is attached. Even though there are complicated patterns in the background of an image, the needle 18 can be clearly recognized without being affected by the shapes in the background. Since an electron beam signal irradiated to the background of the needle is not reflected on an image, the background is expressed in a uniform gray tone of a noise level. On the other hand, the carbon deposition film DM appears to be somewhat darker than the background gray tone, and thus the tip of the carbon deposition film DM cannot be clearly discerned on an absorption current image. Since it is difficult to recognize an actual tip position of a needle to which a carbon deposition film DM is attached, on an absorption current image, if the needle 18 is moved relying only on the absorption current image, there is a high possibility that the tip of the needle collides with a sample piece Q.

Therefore, the coordinates of the actual tip of the needle 18 can be obtained from the coordinates C of the tip of the carbon deposition film DM in a manner described below. Here, the image of FIG. 6b will be referred to as a first image.

The process of acquiring an absorption current image (first image) of the needle 18 corresponds to Step S044.

Next, image processing is performed on the first image of FIG. 6b to extract a region brighter than the background (step S045).

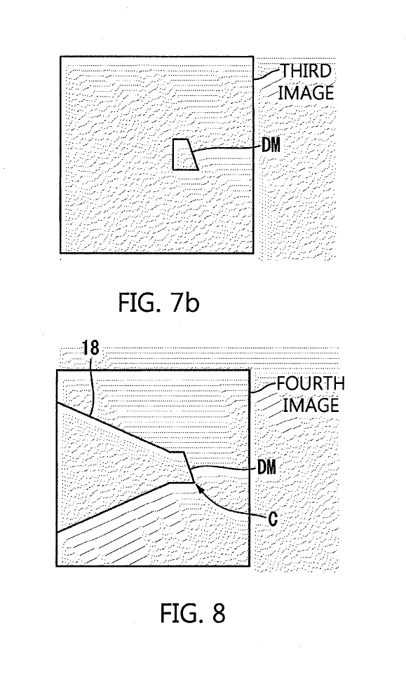

FIG. 7a is a schematic diagram illustrating a region that is brighter than the background, the region being extracted by performing image processing on the first image of FIG. 6b. When a brightness difference between the background and the needle 18 is small, image contrast may be enhanced to increase the brightness difference between the background and the needle. In this way, an image in which a region (part of the needle 18) brighter than the background is enhanced obtained, and this image is referred to as a second image herein. The second image is stored in the computer 22.

Next, a region darker than the brightness of the background in the first image of FIG. 6b is extracted in Step S046.

FIG. 7b is a schematic diagram illustrating a region that is darker than the background, the region being extracted by performing image processing on the first image of FIG. 6b. Only the carbon deposition film DM at the tip of the needle is extracted and shown. When a brightness difference between the background and the carbon deposition film DM is small, image contrast may be enhanced to increase the brightness difference between the background and the carbon deposition film DM on image data. In this way, an image in which a region darker than the background is manifested is obtained. Here, this image is referred to as a third image, and the third image is stored in the computer 22.

Next, an image is synthesized from the second image and the third image stored in the computer 22 in Step S047.

FIG. 8 is a schematic diagram of a synthesized display image. In order to make an object in the image clearly seen, only the outline of the area of the needle 18 in the second image and the outline of the carbon deposition film DM in the third image are displayed by a line, and the background, the needle 18, and a portion except for the periphery of the carbon deposition film DM are displayed to be transparent. Alternatively, only the background may be displayed to be transparent, and the needle 18 and the carbon deposition film DM may be displayed in the same color or the same tone. As described above, since the second image and the third image are originally based on the first image, as long as only either one of the second image and the third image is not deformed, for example, enlarged, reduced, or rotated, the synthesized image has a shape on which the first image is reflected. Here, the synthesized image is referred to as a fourth image, and the fourth image is stored in the computer. Since the fourth image is acquired by performing the process of adjusting the contrast and emphasizing the outline based on the first image, the needle shapes of the first image and the fourth image are exactly the same, the outline of the needle becomes clearer in the fourth image, and the tip of the carbon deposition film DM is more clearly seen in the fourth image than that in the first image.

Next, from the fourth image, the tip of the carbon deposition film DM, i.e., the coordinates of the actual tip of the needle 18 on which the carbon deposition film DM is deposited are obtained in Step S048.

The fourth image is read from the computer 22 and displayed to determine the coordinates of the actual tip of the needle 18. The point C which protrudes most in the axial direction of the needle 18 is the actual tip of the needle and is automatically determined through image recognition, and the coordinates of the tip are stored in the computer 22.

Next, in order to further improve the accuracy of template matching, an absorption current image of the tip of the needle in the same observation field of view as that used in Step S044 is used as a reference image, a template image is formed by extracting only a portion including the tip of the needle from reference image data, with reference to the needle tip coordinates obtained in Step S048, and the template image is registered in the computer 22 in association with the reference coordinates (needle tip coordinates) of the needle tip, which are obtained in Step S048, in Step S050.

Next, the computer 22 performs the following processing as a process of bringing the needle 18 close to the sample piece Q.

In Step S050, although the same observation field of view as that in Step S044 is used, the present invention is not limited thereto. In the case where a beam scanning standard is managed, the field of view used in Step S050 is not limited to the same field of view. Further, in the description of the Step S050, the template includes the tip portion of the needle. However, as long as the actual coordinates are associated with the reference coordinates, a template not including the tip portion can be used as the template. Although a secondary electron image is taken as an example in FIG. 7, a reflected electron image also can be used to identify the coordinates of the tip C of the carbon deposition film DM.

Since the computer 22 uses image data actually acquired before the movement of the needle 18 as reference image data, highly accurate pattern matching can be performed regardless of the shapes of the individual needles 18. Furthermore, since the computer 22 acquires image data in a state where there is no complicated structure in the background, the accurate coordinates of the actual needle tip can be obtained. In addition, it is possible to acquire a template by which the shape of the needle 18 can be clearly discerned while preventing the influence of the background.

When acquiring image data for each image, the computer 22 uses image acquisition conditions such as suitable magnification, luminance, contrast, and the like that are previously recorded, in order to increase the recognition accuracy of an object.

Further, the sequence of the process (Step S020 to Step S027) of creating the templates of the columnar portions 34 and the process (Step S030 to Step S050) of creating the template of the needle 18 may be reversed. However, when the process (Step S030 to Step S050) of preparing the template of the needle is performed ahead, the flow E returning from Step S280 to be described later is also interlocked.

<Sample Piece Pickup Process>

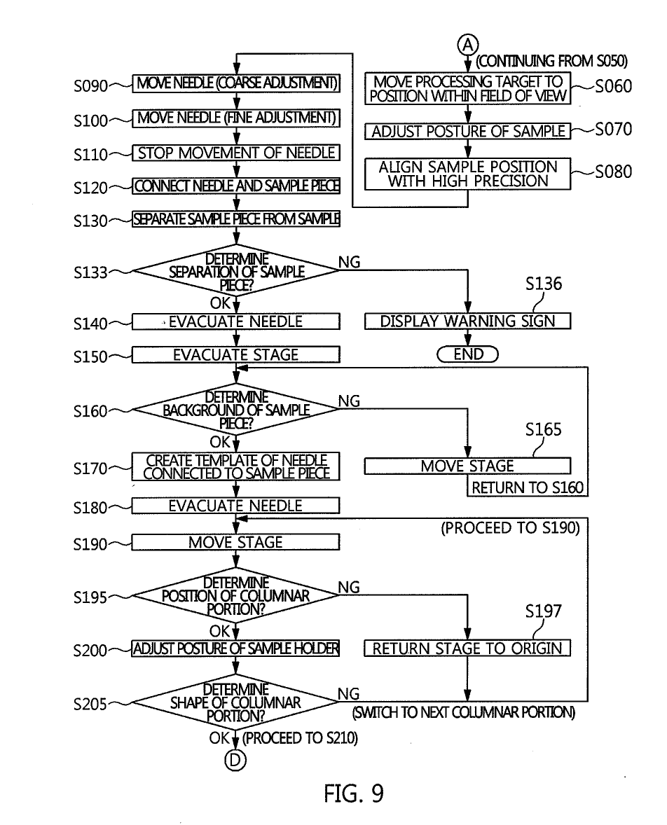

FIG. 9 is a flowchart illustrating the flow of a process of picking up a sample piece Q from a sample S during an automatic sampling operation performed by the charged particle beam apparatus 10 according to the embodiment of the present invention. Here, the term “pickup” means to separate and extract the sample piece Q from the sample S by using a focused ion beam or a needle.

First, the computer 22 causes the stage driving mechanism 13 to move the stage 12 to put a target sample piece Q in the field of view of a charged particle beam. The stage driving mechanism 13 may be operated with reference to the position coordinates of a target reference mark Ref.

Next, the computer 22 uses image data of the charged particle beam to recognize the reference mark Ref formed on the sample S in advance. With the use of the recognized reference mark Ref, the computer 22 recognizes the position of the sample piece Q from the relative positional relationship between a known reference mark Ref and the sample piece Q, and moves the stage such that the sample piece Q enters the observation field of view in Step S060.

Next, the computer 22 causes the stage driving mechanism 13 to drive the stage 12, thereby rotating the stage 12 about the Z axis by an angle corresponding to a posture control mode such that the sample piece Q is in a predetermined posture (for example, a posture suitable for extraction by the needle 18, etc.) in Step S070.

Next, the computer 22 recognizes the reference mark Ref using the image data of the charged particle beam, recognizes the position of the sample piece Q by referring to the relative positional relationship between a known reference mark Ref and the sample piece Q, and adjusts the position of the sample piece Q in Step S080. Next, the computer 22 performs the following processing as a process of bringing the needle 18 close to the sample piece Q.

The computer 22 performs a needle movement (coarse adjustment) for moving the needle 18 by using the needle driving mechanism 19 in Step S090. The computer 22 recognizes the reference marks Ref (see FIG. 2) using image data of images of the sample S respectively formed by a focused ion beam and an electron beam. The computer 22 sets a movement target position AP of the needle 18 using the recognized reference marks Ref.

Here, the movement target position AP is set to a position close to the sample piece Q. The movement target position AP is set to, for example, a position close to one side of the sample piece Q, on the opposite side of the support portion Qa. The computer 22 obtains a positional relationship of the movement target position AP with respect to a processing range F of the sample piece Q when forming the sample piece Q. The computer 22 records information on the relative positional relationship between the processing range F and the reference mark Ref when forming the sample piece Q through irradiation of a focused ion beam. The computer 22 moves the tip of the needle 18 toward the movement target position AP in a three-dimensional space by using the recognized reference mark Ref and using the relative positional relationship among the reference mark Ref, the processing range F, and the movement target position AP (see FIG. 2). The computer 22 first moves the needle 18 in the X direction and the Y direction and then moves the needle 18 in the Z direction when three-dimensionally moving the needle 18.

When moving the needle 18, the computer 22 can precisely and accurately grasp the three-dimensional positional relationship between the needle 18 and the sample piece Q, using the reference mark Ref formed on the sample S during an automatic process of forming the sample piece Q and observing the sample piece from different directions by using an electron beam and a focused ion beam, and thus can appropriately move the needle 18.

Although the above description describes that the computer 22 moves the tip of the needle 18 toward the movement target position AP in a three-dimensional space, using the reference mark Ref and using a relative positional relationship among the reference mark Ref, the processing range F, and the movement target position AP, the movement of the tip of the needle is not limited thereto. Alternatively, the computer 22 may move the tip of the needle 18 toward the movement target position AP in a three-dimensional space by using a relative positional relationship between the reference mark Ref and the movement target position AP but without using a positional relationship with the processing range F.

Next, the computer 22 performs a needle movement process (fine adjustment) of moving the needle 18 using the needle driving mechanism 19 in Step S100. The computer 22 repeatedly performs template matching by using the template created in Step S050, and moves the needle 18 in a three-dimensional space from the movement target position AP to a connection processing position by using the needle tip coordinates obtained in Step S047 as the tip position of the needle 18 within a SEM image while irradiating a charged particle beam to an irradiation region in which the movement target position AP is included.

Next, the computer 22 performs a process of stopping movement of the needle 18 in Step S110.

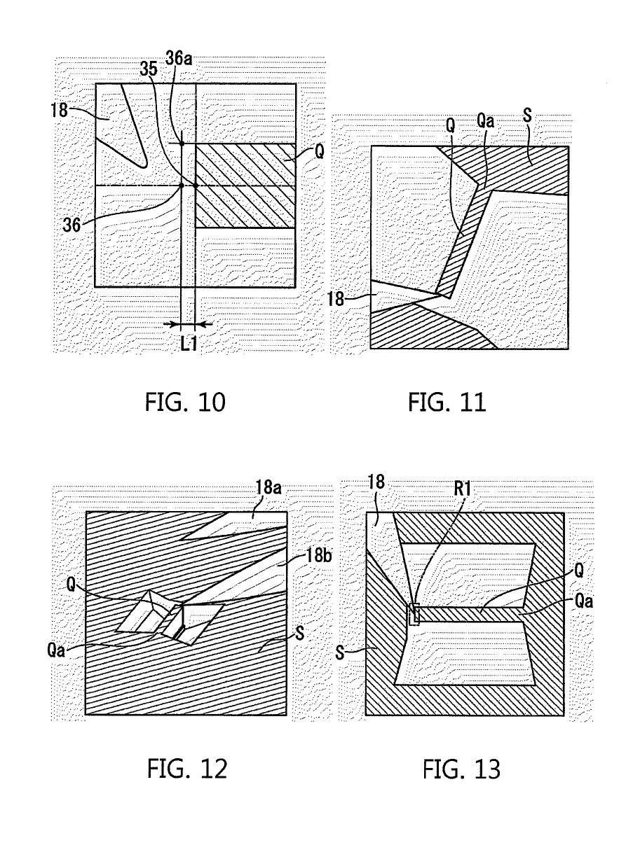

FIG. 10 is a diagram for describing a positional relationship between a needle and a sample piece when the needle is connected to the sample piece, in which an end portion of the sample piece Q is enlarged. In FIG. 10, the end portion (end surface) of the sample piece Q to which the needle 18 is to be connected is arranged at an SIM image center 35, and a position which is at a predetermined distance L1 from the SIM image center 35, for example, a center position of the width of the sample piece Q is set as the connection processing position 36. The connection processing position may be a position (reference numeral 36a in FIG. 10) on a line extended from the end surface of the sample piece Q. In this case, the position is a convenient position because a deposition film can be easily deposited at the position. The computer 22 sets the upper limit of the predetermined distance L1 to 1 μm, and more preferably sets the predetermined distance to be 100 nm or more and 400 nm or less. When the predetermined distance is less than 100 nm, only the connected deposition film cannot be cut when the needle 18 is separated from the sample piece Q in a later process. That is, there is a risk that even the needle 18 is cut. When the needle 18 is cut, the needle 18 is shortened and the tip of the needle is deformed to be thick. When this is repeated, the needle 18 has to be exchanged, which contradicts the object of the present invention which is to repeatedly perform sampling without stopping. On the contrary, when the predetermined distance.

exceeds 400 nm, the connection by the deposition film is insufficient, which increases a risk of failing to extract the sample piece Q, thereby hindering repeated sampling.

In addition, although the position in the depth direction cannot be illustrated in FIG. 10, the position in the depth direction is previously set to a position at a depth corresponding to half the width of the sample piece Q. However, the position in the depth direction is not limited to this position. The three-dimensional coordinates of the connection processing position 36 are stored in the computer 22.

The computer 22 designates the preset connection processing position 36. The computer 22 operates the needle driving mechanism 19, based on the three-dimensional coordinates of the tip of the needle 18 and the connection processing position 36 in the same SIM image or SEM image, and moves the needle 18 to the predetermined connection processing position 36. The computer 22 stops operation of the needle driving mechanism 19 when the position of the tip of the needle coincides with the connection processing position 36.

FIGS. 11 and 12 illustrate a state in which the needle 18 approaches the sample piece Q. FIG. 11 is a diagram illustrating an image formed by using a focused ion beam of the charged particle beam apparatus 10 according to the embodiment of the present invention, and FIG. 12 is a diagram illustrating an image formed by using an electron beam. FIG. 12 illustrates the states of the needle 18 before and after fine adjustment of the needle. In FIG. 12, a needle 18a is the needle 18 that is disposed at the movement target position and a needle 18b is the needle 18 disposed at the connection processing position 36 after the fine adjustment of the needle 18 is performed. The needles 18a and 18b are the same needle 18. FIGS. 11 and 12 illustrate images respectively formed by a focused ion beam and an electron beam. FIGS. 11 and 12 are different from each other in the observation direction and the observation magnification but are the same in the observation target and the needle 18.

By using such a method of moving the needle 18, the needle 18 can be brought close to and be stopped at the connection processing position 36 in the vicinity of the sample piece Q accurately and quickly.

Next, the computer 22 performs a process of connecting the needle 18 to the sample piece Q in Step S120. The computer irradiates a focused ion beam to an irradiation region including a processing range R1 at the connection processing position 36 while supplying a carbon-based gas serving as a deposition gas to the end surfaces of the sample piece Q and the needle 18 for a predetermined deposition time by using the gas supply unit 17. In this way, the computer 22 performs the process of connecting the sample piece Q and the needle 18 with each other using the deposition film.

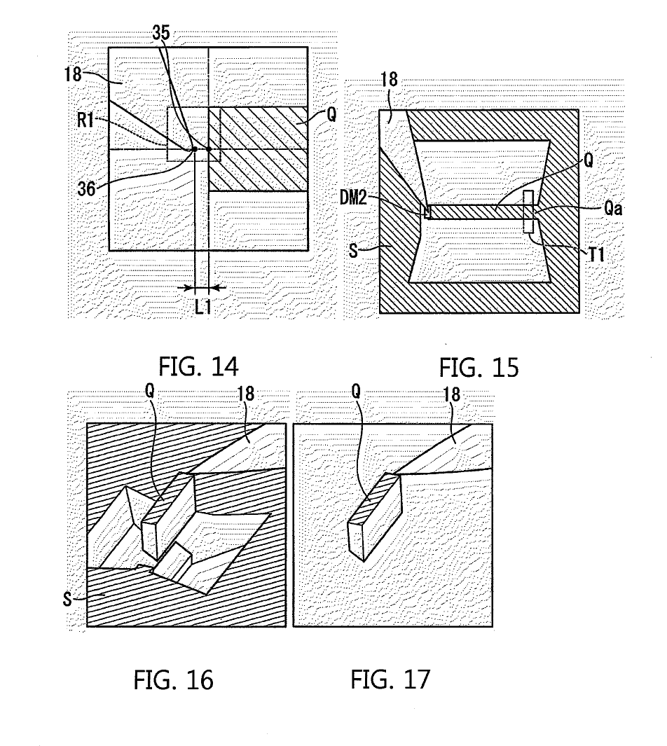

In Step S120, the computer 22 performs the process of connecting the needle 18 with the sample piece Q using the deposition film in a state in which the needle 18 and the sample piece Q are positioned to have a gap therebetween rather than a state in which the needle 18 and the sample piece Q are in direct contact with each other. Therefore, it is possible to prevent the needle 18 from being accidently cut by a focused ion beam when the needle 18 and the sample piece Q are separated from each other by the focused ion beam in a later process. Further, there is another advantage of preventing problems such as damage caused by direct contact between the needle 18 to the sample piece Q from occurring. Furthermore, even through the needle 18 vibrates, it is possible to suppress the vibration from being transmitted to the sample piece Q. Further, even when the movement of the sample piece Q occurs due to the creep phenomenon of the sample S, excessive strain between the needle 18 and the sample piece Q can be suppressed. FIG. 13 illustrates this state. FIG. 13 is a diagram illustrating the processing range R1 (deposition film formation region) including the connection processing position at which the needle 18 and the sample piece Q are connected to each other, in image data formed by a focused ion beam irradiated by the charged particle beam apparatus 10 according to the embodiment of the present invention. FIG. 14 is an enlarged explanatory view of FIG. 13, which makes it easy to understand the positional relationship among the needle 18, the sample piece Q, and the deposition film formation region (for example, the processing range R1). The needle 18 approaches the connection processing position spaced from the sample piece Q by the predetermined distance L1 and stops there. The needle 18, the sample piece Q, and the deposition film formation region (for example, the processing range R1) are set such that the deposition film is formed to straddle the needle 18 and the sample piece Q. The deposition film is also formed in the gap having the predetermined distance L1, and the needle 18 and the sample piece Q are connected with each other by a deposition film.

When connecting the needle 18 to the sample piece Q, the computer 22 makes the sample piece Q connected to the needle 18 take a certain connection posture determined depending on an approach mode previously selected in Step S010 when the sample piece Q connected to the needle 18 is later transferred to the sample piece holder P. The computer 22 sets relative connection postures of the needle 18 and the sample piece Q, respectively corresponding to a plurality of (for example, three) different approach modes to be described later.

The computer 22 may determine a connection state of needle 18 and the sample piece Q connected by the deposition film, by detecting a change in the absorption current of the needle 18. When the absorption current of the needle 18 reaches a predetermined current value, the computer 22 determines that the sample piece Q and the needle 18 are connected by the deposition film, and stops formation of the position film regardless of whether or not a predetermined deposition time has elapsed.

Next, the computer 22 performs a process of cutting the supporting portion Qa that connects the sample piece Q to the sample S in Step S130. The computer 22 designates a preset cutting position T1 within the supporting portion Qa using the reference mark Ref formed on the sample S.

The computer 22 separates the sample piece Q from the sample S by emitting the focused ion beam to the cutting position T1 for a predetermined cutting process time. FIG. 15 illustrates this state, and is a diagram illustrating the cutting position T1 at the supporting portion Qa between the sample S and the sample piece Q, in the image data formed by a focused ion beam irradiated by the charged particle beam device 10 according to the embodiment of the present invention.

The computer 22 determines whether or not the sample piece Q is separated from the sample S by detecting electrical conduction between the sample S and the needle 18 in Step S133.

In the case where electrical conduction between the sample S and the needle 18 is not detected, the computer 22 determines that the sample piece Q is separated from the sample S (OK), and the computer 22 performs subsequent processing (i.e., Step S140 and subsequent steps). On the other hand, when electrical conduction between the sample S and the needle 18 is detected after the completion of the cutting process, that is, after the cutting of the supporting portion Qa between the sample piece Q and the sample S at the cutting position T1 is completed, the computer 22 determines that the sample piece Q is not separated from the sample S (NG). When determining that the sample piece Q is not separated from the sample S (NG), the computer 22 notifies an operator of the state in which separation of the sample piece Q and the sample S is not completed, by displaying information indicating the state on the display device 21 or by generating a warning sound in Step S136. Then, the subsequent processing is interrupted here. In this case, the computer 22 may cut the deposition film (a deposition film DM2 to be described later) connecting the sample piece Q and the needle 18, by irradiating the deposition film with the focused ion beam, thereby separating the sample piece Q and the needle 18 from each other, and then return the needle 18 to an initial position in Step S060. The needle 18 returned to its initial position performs sampling the next sample piece Q.

Next, the computer 22 executes a needle evacuation process in Step S140. The computer 22 raises the needle 18 in the vertical direction (that is, the positive direction of the Z direction) by a predetermined distance (for example, 5 μm) by using the needle driving mechanism 19. FIG. 16 illustrates this state, and is a diagram illustrating a state in which the needle 18 connected to the sample piece Q is evacuated, in the image data formed by an electron beam of the charged particle beam apparatus 10 according to the embodiment of the present invention.

Next, the computer 22 performs stage evacuation processing in Step S150. As illustrated in FIG. 16, the computer 22 causes the stage driving mechanism 13 to move the stage 12 by a predetermined distance. For example, the computer 12 lowers the stage 12 in the vertical direction by 1 mm, 3 mm, or 5 mm (i.e., the negative direction of the Z direction). After lowering the stage 12 by the predetermined distance, the computer 22 moves the nozzle 17a of the gas supply unit 17 away from the stage 12. For example, the computer 22 raises the nozzle 17a in the vertical direction to a standby position which is directly above the stage 12. FIG. 17 illustrates this state, and is a diagram illustrating a state in which the stage 12 is evacuated from the needle 18 connected to the sample piece Q, in image data formed by an electron beam of the charged particle beam apparatus 10 according to the embodiment of the present invention.

Next, the computer 22 operates the stage driving mechanism 13 such that there is no structure in the background of an image including the needle 18 and the sample piece Q connected to each other. This is to recognize without fail the edges (outlines) of the needle 18 and the sample piece Q from the image data of the sample piece Q formed by each of the focused ion beam and the electron beam, at the time of preparing templates of the needle 18 and the sample piece Q in a subsequent process (step). The computer 22 executes a process of moving the stage 12 by a predetermined distance. When it is determined whether or not there is a problem with the background of the image of the sample piece Q in Step S160 and, as a result, it is determined that there is no problem with the background, the processing proceeds to the next step, i.e., Step S170. When there is a problem with the background, the stage 12 is moved again by a predetermined amount in Step S165, and the processing is returned to the background determination process of Step S160. The background determination process is repeated until the background has no problem.

The computer 22 creates templates of the needle 18 and the sample piece Q in Step S170. The computer 22 creates templates of the needle 18 and the sample piece Q that are in a rotated posture (i.e., a posture in which the sample piece Q is connected to the columnar portion 34 of the sample base 33) in which the needle 18 to which the sample piece Q is fixed is rotated as necessary. Thereby, in accordance with the rotation of the needle 18, the computer 22 three-dimensionally recognizes the edges (outlines) of the needle 18 and the sample piece Q from the image data formed by each of the focused ion beam and the electron beam. In an approach mode in which the rotation angle of the needle 18 is 0°, the computer 22 may recognize the edges (outlines) of the needle 18 and the sample piece Q from the image data formed by the focused ion beam without using an electron beam.

When the computer 22 instructs the stage driving mechanism 13 and the needle driving mechanism 19 to move the stage 12 to a position where there is no structure in the background of the needle 18 and the sample piece Q, the computer searches for the needle 18 by setting an observation magnification to a low magnification when the needle 18 has not reached the position as instructed. When failing to find the needle 18, the computer 22 initializes the coordinates and moves the needle 18 to the initial setting position.

In the template creation process (Step S170), first, the computer 22 acquires templates (reference image data) of the sample piece Q and the tip of the needle 18 connected to the sample piece Q, for template matching. The computer 22 irradiates charged particle beams (each of a focused ion beam and an electron beam) to the needle 18 while scanning an irradiation position. The computer 22 acquires image data from each of a plurality of different directions in which the secondary charged particles R (secondary electrons etc.) are emitted from the needles 18 by performing irradiation of charged particle beams. The computer 22 acquires image data through irradiation of the focused ion beam and irradiation of the electron beam. The computer 22 records image data acquired from two different directions as templates (reference image data).

Since the computer 22 uses actual image data of the sample piece Q and the needle 18 connected to the sample piece Q, which are actually processed by a focused ion beam, as the reference image data, highly accurate pattern matching can be performed regardless of the shapes of the sample piece Q and the needle 18.

In order to increase the recognition accuracy of the shapes of the sample piece Q and the needle 18 connected to the sample piece Q when acquiring each of the image data, the computer 22 uses image acquisition conditions such as an appropriate magnification, luminance, contrast, etc. which are previously recorded.

In the template creation process (Step S170), the computer 22 generates an error signal when an abnormality occurs in processing such as image recognition of the needle 18 and the sample piece Q. For example, when the edges (outlines) of the needle 18 and the sample piece Q cannot be extracted from the image data, the computer 22 again acquires new image data and attempts to extract edges (outlines) of the sample piece Q and the needle 18 from the new image data. When the edges (outlines) of the sample piece Q and the needle 18 cannot be extracted from the new image data, an error signal is generated. This error signal automatically activates an error processing process to be described later. At this point, with respect to the sample piece Q connected to the needle 18, the subsequent processing (that is, the processing of Step S170 and subsequent steps) is interrupted and a process of destroying the needle 18 is performed.

Next, the computer 22 performs a process of evacuating the needle in Step S180. This is to prevent the needle from coming into unintentional contact with the stage 12 during the subsequent stage movement process. The computer 22 moves the needle 18 by a predetermined distance by using the needle driving mechanism 19. For example, the needle 18 is raised in the vertical direction (that is, the positive direction of the Z direction). Alternatively, the needle 18 may stay on the spot and the stage 12 may be moved by a predetermined distance. For example, the stage 12 may be lowered in the vertical direction (that is, the negative direction of the Z direction). The needle evacuation direction is not limited to the vertical direction described above but it may be the axial direction of the needle or a direction of a predetermined position for evacuation of the needle. The predetermined position may be a position at which the sample piece Q connected to the tip of the needle is not in contact with any structure inside the sample chamber or is unlikely to be irradiated with a focused ion beam.

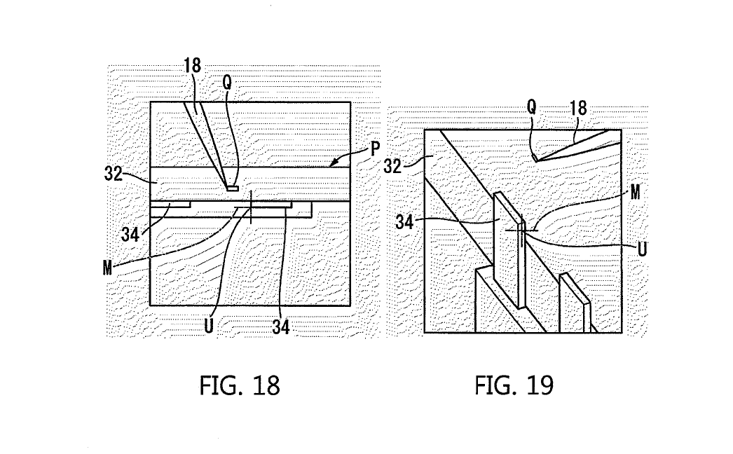

Next, the computer 22 moves the stage 12 by using the stage driving mechanism 13 so that a specific sample piece holder P registered in Step S020 falls within an observation field of view of a charged particle beam in Step S190. FIGS. 18 and 19 illustrate this state. Particularly, FIG. 18 is a schematic diagram of an image formed by a focused ion beam generated by the charged particle beam apparatus 10 according to the embodiment of the present invention. Specifically, FIG. 18 illustrates an attachment position on the columnar portion 34, at which the sample piece Q is attached to the columnar portion 34. FIG. 19 is a schematic diagram of an image formed by an electron beam, and illustrates an attachment position U on the columnar portion 34, at which the sample piece Q is attached to the columnar portion 34.

Here, it is determined whether or not a columnar portion 34 of a target sample piece holder P falls within a region of the observation field of view in Step S195. When the target columnar portion 34 is disposed within the observation field of view, the processing proceeds to the next step, i.e., Step S200. When the target columnar portion 34 is not disposed within the observation field of view, that is, when the stage is not correctly operated with respect to specified coordinates, the stage coordinates designated immediately before are initialized and the stage is returned to the origin position of the stage 12 in Step S197. Then, the coordinates of the target columnar portion 34 which is required to be registered in advance are designated, the stage 12 is driven in Step S190, and the processing is repeated until the columnar portion 34 falls within the observation field of view.

Next, the computer 22 moves the stage 12 by using the stage driving mechanism 13 to adjust a horizontal position of the sample piece holder P, and then rotates and tilts the stage 12 by an angle corresponding to a desired posture control mode so that the sample piece holder P is in a predetermined posture in Step S200.

Through Step S200, the postures of the sample piece Q and the sample piece holder P can be adjusted so that the surface (end surface) of the original sample S is parallel or perpendicular to the end surface of the columnar portion 34. In particular, given that the sample piece Q fixed to the columnar portion 34 is thinned by a focused ion beam, it is preferable that the postures of the sample piece Q and the sample piece holder P are adjusted such that the surface (end surface) of the original sample S becomes perpendicular to the irradiation axis of the focused ion beam. Alternatively, the postures of the sample piece Q and the sample piece holder P may be adjusted such that the surface (end surface) of the sample piece Q to be fixed to the columnar portion 34 is perpendicular to the columnar portion 34 and is disposed on the downstream side in the direction in which the focused ion beam is incident.

Here, it is determined whether or not the shape of the columnar portion 34 of the sample piece holder P is normal in Step S205. An objective of the shape determination of the columnar shape 34 performed in Step S205 is to check whether a specific columnar portion 34 is accidently deformed, damaged, or missing due to any accidental contact or the like after the image of the columnar portion 34 is registered in Step S023. When a columnar portion 34 is determined as being normal by having a shape with no problem in Step S205, the processing proceeds to the next step, i.e., Step S210. Conversely, when the columnar portion 34 is determined as being defective, the processing is returned to Step S190 in which the stage is moved so that the next columnar portion 34 falls within the observation field of view.

When it is determined that a designated columnar portion is not disposed in the observation field of view although the computer 22 instructs the stage driving mechanism 13 to move the stage 12 such that the designated columnar portion 34 falls within the observation field of view, the computer 22 initializes the coordinates of the position and moves the stage 12 to an initial position thereof.

Next, the computer 22 moves the nozzle 17a of the gas supply unit 17 to a position close to a focused ion beam irradiation position. For example, the nozzle 17a is lowered in the vertical direction toward the processing position from the standby position that is directly above the stage 12.

In the column shape determination (Step S205), in the case where the computer 22 cannot determine whether the shape of the columnar portion 34 is normal or abnormal due to an abnormality occurring in processing such as image recognition of the columnar portion 34, an error signal is generated. For example, in the case where the columnar portion 34 cannot be recognized from the image data, the computer 22 again acquires new image data and attempts to recognize the columnar portion 34 from the new image data. When the columnar portion 34 cannot be recognized from the new image data, an error signal is generated. This error signal automatically activates an error processing process to be described later. At this point, with respect to the sample piece Q connected to the needle 18, the subsequent processing (processing of Step S210 and subsequent steps thereof) is interrupted, and the sample piece is removed from the needle 18.

<Sample Piece Mounting Process>

Here, the term “sample piece mounting process” refers to a process of transferring a sample piece Q that is extracted from a sample to a sample piece holder P.

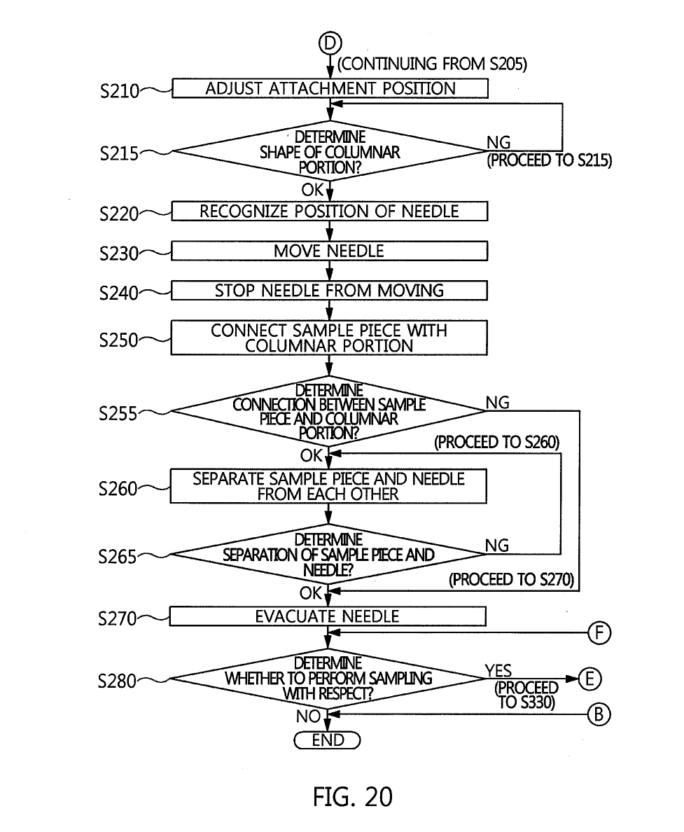

FIG. 20 is a flowchart illustrating a process of mounting (transferring) a sample piece Q to a predetermined columnar portion 34 of a predetermined sample piece holder P during the automatic sampling operation of the charged particle beam device 10 according to the embodiment of the present invention 7.

By using image data of images respectively formed by a focused ion beam and an electron beam, in Step S210, the computer 22 recognizes a transfer position of a sample piece Q recorded in Step S020 Step S210. The computer 22 performs template matching of a columnar portion 34. The computer 22 performs the template matching in order to confirm that a columnar portion 34 appearing in a region of the observation field of view among a plurality of columnar portions 34 of a comb-shaped sample base 33 is a previously designated columnar portion 34. The computer 22 performs template matching with respect to the image data of images respectively formed by a focused ion beam and an electron beam, using the templates of the respective columnar portions 34 created in the template preparation process (i.e., Step S020) of the columnar portions 34.

In Step S215, the computer 22 determines whether a problem such as absence of the columnar portion 34 or the like is found during the template matching for each columnar portion 34, which is performed after the movement of the stage 12. When a problem is found in the shape of the columnar portion 34 (NG), the columnar portion 34 to which the sample piece Q is to be transferred is skipped and the process is performed with respect to the next columnar portion 34 adjacent to the columnar portion 34 which has been determined as having a problem. Thus, the switched next columnar portion 34 undergoes template matching for defect checking. Through this process, a columnar portion 34 to which a sample piece Q can be transferred is determined. If there is no problem with the shape of the columnar portion 34, the processing proceeds to the next step, i.e., Step S220.

Further, the computer 22 may extract an edge (outline) from image data of a predetermined region (a region including at least a columnar portion 34), and may use this edge pattern as a template. Further, when an edge (outline) cannot be extracted from the image data of the predetermined region (region including at least a columnar portion 34), the computer 22 acquires new image data. The extracted edge may be displayed on the display device 21 and then undergo template matching with an image formed by irradiating a region corresponding to the observation field of view with a focused ion beam.

In the columnar portion shape determination process (Step S215), when template matching for each template cannot be normally performed due to an abnormality occurring in the processing such as image recognition of the columnar portion 34, or due to deformation, breakage, or absence of the columnar portion 34, the computer 22 generates an error signal. When the columnar portion 34 cannot be recognized from image data or the edge (outline) of the columnar portion 34 cannot be extracted, the computer acquires new image again, and tries to recognize the columnar portion 34 from the new image data or to extract the edge (outline). Then, when it is also difficult to extract the edge (outline) of the columnar portion 34 or to recognize the columnar portion 34 even from the new image data, the computer generates an error signal. This error signal automatically activates the error processing process as described below, interrupts the subsequent processing (processing of Step S220 and subsequent steps performed in a normal condition) with respect to the sample piece Q connected to the needle 18, and performs a destroying process of removing the sample piece from the needle 18.

The computer 22 causes the stage driving mechanism 13 to drive the stage 12 such that the attachment position of the sample piece, which is recognized through irradiation of an electron beam, coincides with the attachment position recognized through irradiation of a focused ion beam. The computer 22 causes the stage driving mechanism 13 to drive the stage 12 such that the attachment position U of the sample piece Q coincides with the field center (processing position) of a field of view.

Next, the computer 22 performs Step S220 to Step S250, as a process of bringing the sample piece Q connected to the needle 18 into contact with the sample piece holder P.

First, the computer 22 recognizes the position of the needle 18 in Step S220. The computer 22 detects the absorption current flowing into the needle 18 by irradiating the needle 18 with charged particle beams, and generates absorption current image data. The computer 22 obtains absorption current image data formed through irradiation of a focused ion beam and absorption current image data formed through irradiation of an electron beam irradiation. The computer 22 detects the position of the tip of the needle 18 in a three-dimensional space using the absorption current image data obtained from two different directions.

The computer 22 causes the stage driving mechanism 13 to drive the stage 12 by using the detected tip position of the needle 18 and may set the tip position of the needle 18 as the center position (field center) of a preset field of view.

Next, the computer 22 performs a sample piece mounting process. First, the computer 22 performs template matching in order to accurately recognize the position of the sample piece Q connected to the needle 18. The computer 22 performs template matching with image data obtained through irradiation of a focused ion beam and image data formed through irradiation of an electron beam, by using the templates of the needle 18 and sample piece Q connected to each other, which are previously created in the template preparation process (Step S170) of the needle 18 and sample piece Q.

When extracting an edge (outline) from a predetermined region (including at least the needle 18 and the sample piece Q) in the image data during the template matching, the computer 22 displays the extracted edge on the display device 21. Further, in the case where the edge (outline) cannot be extracted from the predetermined region (region including at least the needle 18 and the sample piece Q) in the image data during the template matching, the computer 22 acquires new image data.

Then, the computer 22 measures the distance between the sample piece Q and the columnar portion 34, based on the result of the template matching between the templates of the needle 18 and the sample pieces Q and the template of the columnar portion 34 that is a target to which the sample piece Q is to be attached, by using image data formed through irradiation of a focused ion beam and image data formed through irradiation of an electron beam.

Then, the computer 22 finally transfers the sample piece Q to the columnar portion 34 that is a target to which the sample piece Q is to be attached, by moving the sample piece Q within a plane parallel to the stage 12.

In this template matching process, when a problem occurs during processing such as image recognition of a predetermined region (region including at least the needle 18 and the sample piece Q), for example, when the edge (outline) cannot be extracted from the image data, the computer 22 again acquires image data and again tries to extract an edge (outline) from the new image data. However, when the edge (outline) cannot be extracted even from the new image data, the computer 22 generates an error signal. This error signal automatically activates the error processing process to be described later. At this point, with respect to the sample piece Q connected to the needle 18, the subsequent processing (that is, processing of Step S230 and subsequent steps) is interrupted. Then, a process of removing the sample piece from the needle 18 is performed.

In this sample piece mounting process, first, the computer 22 performs a needle movement process of moving the needle 18 by using the needle driving mechanism 19 in Step S230. Based on the template matching using the templates of the needle 18 and the sample piece Q and the template of the columnar portion 34 in the image data formed through irradiation of the focused ion beam and the image data formed through irradiation of the electron beam, the computer 22 measures the distance between the sample piece Q and the columnar portion 34. The computer 22 moves the needle 18 in a three-dimensional space in accordance with the measured distance so that the needle 18 can face the attachment position where the sample piece Q is to be attached to the columnar portion 34.

In this template matching process (Step S230), when it is difficult to normally measure the distance between the sample piece Q and the columnar portion 34 due to an abnormality occurring in processing such as image recognition of each of the image data, the computer 22 generates an error signal. For example, when the computer 22 cannot recognize the sample piece Q and the columnar portion 34 from each of the image data, the computer 22 again acquires image data and recognizes the sample piece Q and the columnar portion 34 from new image data. When the sample piece Q and the columnar portion 34 cannot be recognized even from the new image data, the computer 22 generates an error signal. This error signal automatically activates the error processing process to be described later. At this point, with respect to the sample piece Q connected to the needle 18, the subsequent processing (that is, the processing of Step S240 and subsequent steps) is interrupted and a process of removing the sample piece from the needle 18 is performed.

Next, the computer 22 stops the needle 18 by leaving a predetermined gap L2 between the columnar portion 34 and the sample piece Q in Step S240. The computer 22 sets the gap L2 to 1 μm or less, and preferably the gap L2 is set to be 100 nm or more and 500 nm or less.

Although the gap L2 is 500 nm or more, the sample piece can be connected to the columnar portion. However, it is undesirable because a connection time required for connecting the columnar portion 34 with the sample piece Q using a deposition film excessively increases. Therefore, the gap which is greater than 1 μm is not desirable. As the gap L2 is decreased, the connection time required for connecting the columnar portion 34 with the sample piece Q using the deposition film is shortened. However, it is important that the columnar portion and the sample piece are not in direct contact with each other.

When providing the gap L2 between the columnar portion 34 and the sample piece Q, the computer 22 may provide the gap L2 by detecting absorption current images of the columnar portion 34 and the needle 18.

The computer 22 checks whether the sample piece Q is cut away from the needle 18 after the sample piece Q is transferred to the columnar portion 34, by detecting electrical conduction between the columnar portion 34 and the needle 18 or detecting the absorption current images of the columnar portion 34 and the needle 18.

When the computer 22 cannot detect electrical conduction between the columnar portion 34 and the needle 18, the computer 22 switches its operation so as to detect the absorption current images of the columnar portion 34 and the needle 18.

Further, when the computer 22 cannot detect electrical conduction between the columnar portion 34 and the needle 18, the computer 22 may stop the sample piece Q from being transferred, then cut the sample piece Q from the needle 18, and then perform a needle trimming process.

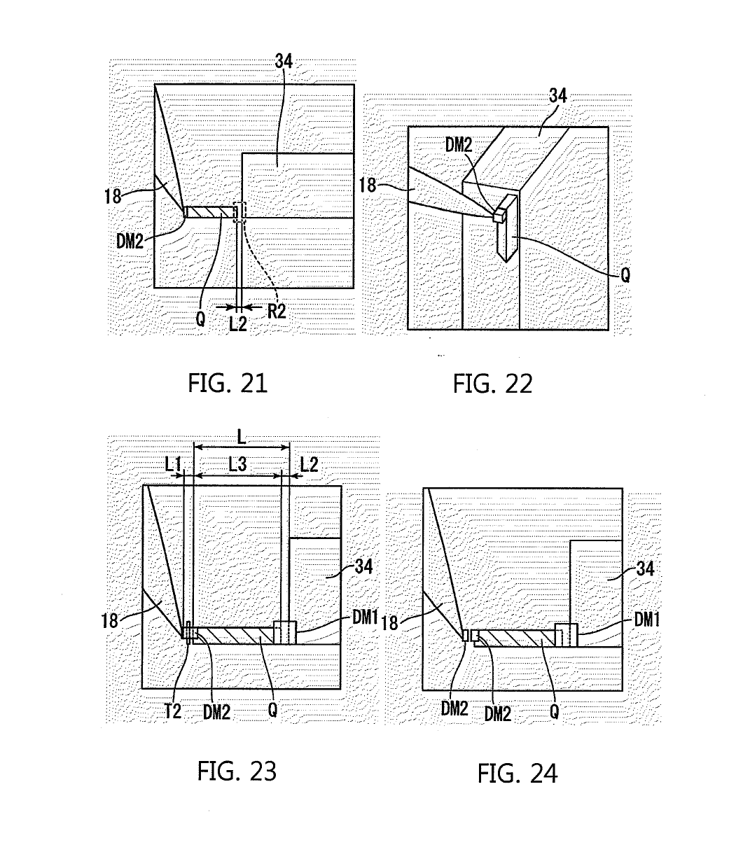

Next, the computer 22 performs a process of connecting the sample piece Q connected to the needle 18 to the columnar portion 34 in Step S250. FIGS. 21 and 22 are schematic diagrams of enhanced-magnification images as compared with FIGS. 18 and 19, respectively. The computer 22 arranges the sample piece Q such that one side of the sample piece Q and one side of the columnar portion 34 are in a straight line as illustrated in FIG. 21 and an upper end surface of the sample piece Q and an upper end surface of the columnar portion 34 are flush with each other as illustrated in FIG. 22. Thus, when the gap L2 equals a predetermined value, operation of the needle driving mechanism 19 is stopped. In a state in which the sample piece Q has stopped moving at the attachment position while having the gap L2 between itself and the columnar portion 34, the computer 22 sets a deposition processing range R2 in which an end portion of the columnar portion 34 is disposed, in the image (see FIG. 21) formed by the focused ion beam. The computer 22 irradiates an irradiation region including the processing range R2 with a focused ion beam for a predetermined time while supplying gas to the surface of the sample piece Q and the columnar portion 34 by using the gas supply part 17. By this operation, a deposition film is formed in a region to which the focused ion beam is irradiated, and the gap L2 is filled with the deposition film, so that the sample piece Q is connected to the columnar portion 34. In the process of fixing the sample piece Q to the columnar portion 34 using the deposition process, the computer 22 stops the deposition process when detecting electrical conduction between the columnar portion 34 and the needle 18.

The computer 22 determines whether the connection between the sample piece Q and the columnar portion 34 is completed in Step S255. Step S255 is performed as described below, for example. An ohmmeter is installed between the needle 18 and the stage 12 in advance to detect electrical conduction between the needle 18 and the stage 12. When the needle 18 and the stage 12 are separated (there is the gap L2 between the needle 18 and the stage 12), electric resistance is infinite. However, when both of them become gradually covered with a conductive deposition film and the gap L2 become gradually filled, the electric resistance gradually increases. When it is confirmed that the electric resistance is equal to or lower than a predetermined resistance value, it is determined that the needle 18 and the stage 12 are electrically connected with each other. Further, from a prior study, when the electrical resistance between the needle 18 and the stage 12 reaches the predetermined resistance value, it is determined that the deposition film has sufficient mechanical strength and the sample piece Q is reliably connected to the columnar portion 34.

It should be noted that the detection is not limited to detection of electric resistance. Any electrical characteristic that can be measured between the columnar portion and the sample piece Q may be detected. For example, current or voltage may be detected. Further, when a predetermined electric characteristic (electric resistance value, current value, electric potential, etc.) is not detected in a predetermined period of time, the computer 22 extends a deposition film formation time. Further, the computer 22 preliminarily obtains an optimum deposition film formation time required for forming an optimum deposition film in accordance with the gap L2 between the columnar portion 34 and the sample piece Q, a beam condition to be irradiated, and a gas species used for the deposition film, records the obtained deposition film formation time as a predetermined deposition time, and may stop the formation of the deposition film when the predetermined deposition time elapses.

The computer 22 stops the gas supply and the irradiation of the focused ion beam when the connection between the sample piece Q and the columnar portion 34 is confirmed. FIG. 23 illustrates this state, and is a diagram illustrating the image data obtained through irradiation of the focused ion beam of the charged particle beam apparatus 10 according to the embodiment of the present invention and illustrating a deposition film DM1 that connects the sample piece Q fixed to the needle 18 to the columnar portion 34.

In Step S255, the computer 22 may determine whether the sample piece and the columnar portion are connected by the deposition film DM 1 by detecting a change in the absorption current of the needle 18.

When the computer 22 determines that the sample piece Q and the columnar portion 34 are connected by the deposition film DM 1, based on the change in the absorption current of the needle 18, the computer 22 can stop the formation of the deposition film regardless of whether or not the predetermined deposition time has elapsed. When the completion of the connection is confirmed, the processing proceeds to the next step, Step S260. When the connection is not completed, the focused ion beam irradiation and the gas supply are performed for the predetermined deposition time and then stopped. Next, the deposition film DM2 that connects the sample piece Q and the needle 18 is cut by a focused ion beam irradiated thereto, and the sample piece Q at the needle tip is discarded. Next, the needle is evacuated in Step S270.

Next, the computer 22 cuts the deposition film DM 2 that connects the needle 18 and the sample piece Q to separate the sample piece Q from the needle 18 in Step S260.

FIG. 23 illustrates this state. FIG. 23 is a diagram illustrating the cutting position T2 at which the deposition film DM2 connecting the needle 18 and the sample piece Q is cut, in the image data formed by a focused ion beam of the charged particle beam apparatus 10 according to the embodiment of the present invention. The computer 22 sets a position spaced from the side surface of the columnar portion 34 by a first distance as the cutting position T2, in which the first distance is the sum (L+L1/2) of the predetermined distance L, which is the sum (L2+L3) of the gap L2 between the side surface of the columnar portion 34 and the sample piece Q and a size L3 of the sample piece Q, and half the predetermined distance L1 (see FIG. 23) that is the size of the gap between the needle 18 and the sample piece Q. Further, the cutting position T2 may be a position spaced from the side surface of the columnar portion by a second distance that is the sum (L+L1) of the predetermined distance L and the size L1 of the gap between the needle 18 and the sample piece Q. In this case, the deposition film DM2 (carbon deposition film) remaining at the tip of the needle has a small size, and thus the frequency of cleanings (to be described later) of the needle 18 is reduced, which is preferable for continuous automatic sampling.

The computer 22 can separate the needle 18 from the sample piece Q by irradiating the cutting position T2 with a focused ion beam for a predetermined time. The computer 22 irradiates a focused ion beam to the cutting position T 2 for a predetermined time so as to cut only the deposition film DM2, thereby separating the needle 18 from the sample piece Q without cutting the needle 18. In Step S260, it is important to cut only the deposition film DM2. Thereby, the needle 18 that is once set can be repeatedly used without being replaced for a long period of time, so automatic sampling can be repeated continuously and unattended. FIG. 24 illustrates this state, and is a diagram illustrating a state in which the needle 18 is separated from the sample piece Q, which can be observed from the image data of the focused ion beam irradiated by the charged particle beam apparatus 10 according to the embodiment of the present invention. Residue of the deposition film DM 2 is attached to the tip of the needle.

The computer 22 determines whether or not the needle 18 is separated from the sample piece Q by detecting electrical conduction between the sample piece holder P and the needle 18 in Step S265. After completion of the cutting process, that is, even after a focused ion beam is irradiated to the cutting position T2 for a predetermined time to cut the deposition film DM2 connected between the needle 18 and the sample piece Q, when electrical conduction between the sample piece holder P and the needle 18 is still detected, the computer 22 determines that the needle 18 is not disconnected from the sample base 33. When the computer 22 determines that the needle 18 is not separated from the sample piece holder P, the computer 22 displays on the display device 21 the state in which the separation between the needle 18 and the sample piece Q is not completed, or notifies an operator of the state by warning sound. Then, the subsequent processing is interrupted. On the other hand, when electrical conduction between the sample piece holder P and the needle 18 is not detected, the computer 22 determines that the needle 18 is completely separated from the sample piece Q, and performs the subsequent processing.

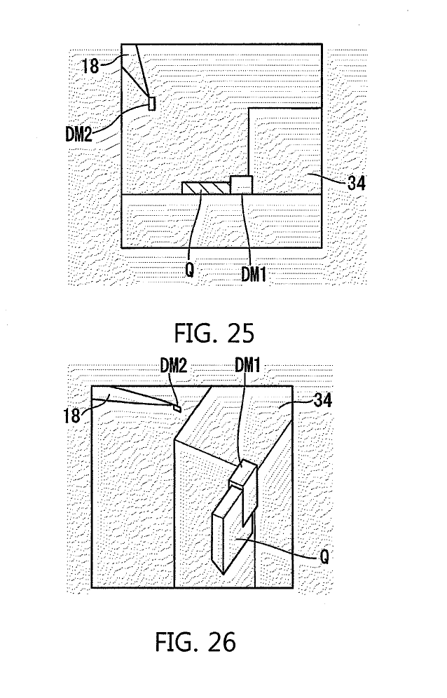

Next, the computer 22 performs a needle evacuation process in Step S270. The computer 22 causes the needle driving mechanism 19 to move the needle 18 away from the sample piece Q by a predetermined distance. For example, the needle 18 is raised by a distance such as 2 mm, 3 mm, or the like in the vertical direction, i.e., the positive direction of the Z direction. FIGS. 25 and 26 illustrate this state, i.e. the state in which the needle 18 is moved to be directly above the sample piece Q. FIG. 25 is a schematic diagram illustrating an image formed by a focused ion beam irradiated by the charged particle beam apparatus 10 according to the embodiment of the present invention, and FIG. 26 is a schematic diagram illustrating an image formed by an electron beam.

Next, it is determined whether to continue sampling at a different position within the same sample S in Step S280. Since the setting of the number of sample pieces to be sampled is registered in advance in Step S010, the computer 22 checks this data and determines whether to perform the next process or not. When sampling is to be continued, the processing proceeds Step S030, and the subsequent processing is continued as described above so that sampling operation can be performed. When sampling is not to be continued, the series of processes is ended.

Note that template creation of the needle in Step S050 may be performed immediately after Step S280. In this case, it is not necessary to perform Step S050 at the time of preparing for sampling of the next sample piece, the overall operation process can be simplified.

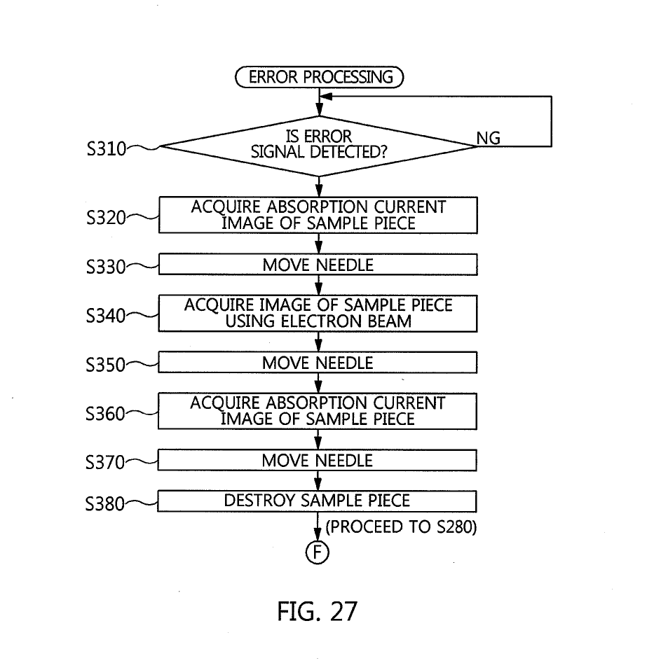

Hereinafter, the error processing process activated by the error signal described above will be described. FIG. 27 is a flowchart of the error processing process.

First, the computer 22 determines whether or not an error signal is detected in Step S310. When the error signal is not detected (NG in Step S310), the computer 22 repeats the determination processing in Step S310. On the other hand, when the error signal is detected (OK in Step S310), the computer 22 performs Step S320.

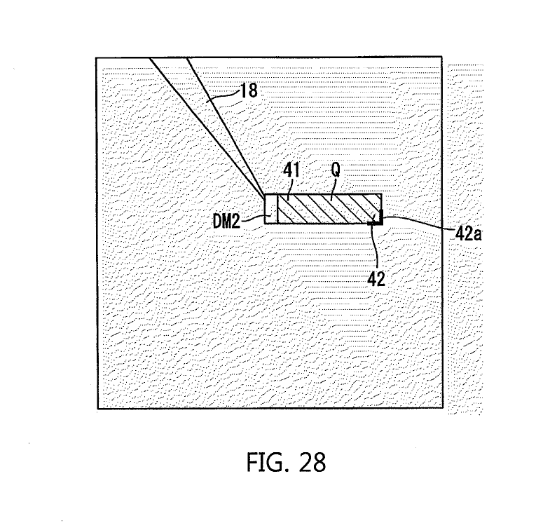

Next, the computer 22 generates absorption current image data by irradiating the sample piece Q connected to the needle 18 while scanning the focused ion beam, and recognizes an edge (outline) of the sample piece Q from this absorption current image data in Step S320. FIG. 28 is a diagram illustrating an example of the edge (drawn in a bold solid line) extracted from the absorption current image data formed by a focused ion beam. For example, from the absorption current image data, the computer 22 extracts, as the edge, a first edge 42a at a first end 42 of the sample piece Q, which is opposite to a second end 41 to which the needle 18 is connected, with reference to the center of the upper end surface (end in the Z direction of FIG. 1) of the sample piece Q.

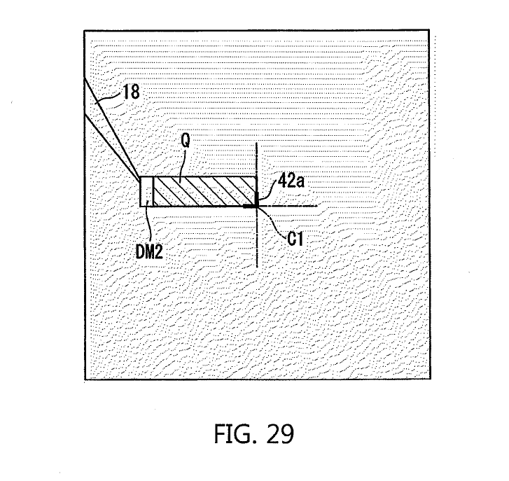

Next, the computer 22 moves the needle 18 so that the position of the edge 42a of the sample piece Q extracted from the absorption current image data coincides with a center position C1 of a field of view of the focused ion beam in Step S330. FIG. 29 is a diagram illustrating a state in which the edge 42a of the sample piece Q has been moved by the needle 18 to the center position C1 of the field of view of the focused ion beam, the state being observed from the absorption current image data formed by a focused ion beam. In this way, the computer 22 adjusts the position of the sample piece Q within the XY plane illustrated in FIG. 1.

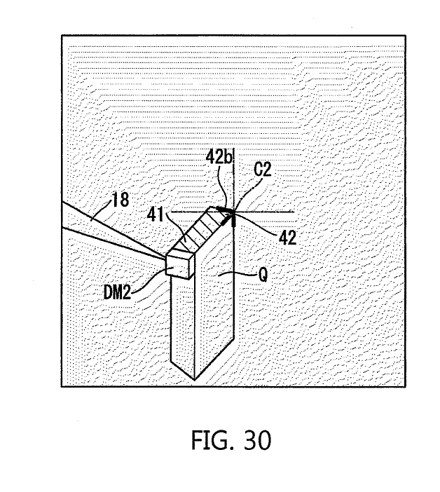

Next, the computer 22 generates image data of secondary electrons by irradiating the sample piece Q connected to the needle 18 with an electron beam, and recognizes an edge (outline) of the sample piece Q from the obtained image data in Step S340. FIG. 30 is a diagram illustrating an example of the edge (drawn in a bold solid line) extracted from the image data formed by the electron beam. For example, from the image data formed by the electron beam, the computer 22 extracts, as the edge, a first edge 42b at a first end 42 of the sample piece Q, which is opposite to a second end to which the needle 18 is connected, with reference to the center of the upper end (end in the Z direction of FIG. 1) of the sample piece Q.

Next, the computer 22 moves the needle 18 so that the position of the edge 42b of the sample piece Q extracted from the image data formed by the electron beam coincides with a center position C2 of a field of view of the electron beam in Step S350. The center position C2 of the field of view of the electron beam and the center position C1 of the field of view of the focused ion beam are the same position in a three-dimensional space of the X axis, the Y axis, and the Z axis illustrated in FIG. 1. In this way, the computer 22 primarily adjusts the position of the sample piece Q in the Z direction illustrated in FIG. 1.

Next, the computer 22 again irradiates the sample piece Q connected to the needle 18 with a focused ion beam, thereby generating absorption current image data, and recognizes an edge (outline) of the sample piece Q from this absorption current image data in Step S360. For example, from the absorption current image data, the computer 22 extracts, as the edge, a first edge 42b at a first end 42 of the sample piece Q, which is opposite to a second end 41 to which the needle 18 is connected, with reference to the center of the upper end (end in the Z axis of FIG. 1) of the sample piece Q.

The computer 22 again moves the needle 18 so that the position of the edge 42a of the sample piece Q extracted from the absorption current image data coincides with the center position C1 of the field of view of the focused ion beam in Step S370. In this way, the computer 22 finely adjusts the position of the sample piece Q within the XY plane illustrated in FIG. 1.

Next, the computer 22 sets a predetermined limited field of view at a region spaced, in the direction of the needle 18, from the center position C1 of the field of view of the focused ion beam, in which the edge 42a of the sample piece Q is disposed, and irradiates a focused ion beam to an irradiation region including the limited field of view, thereby destroying the sample piece Q in Step S380.

For example, the computer 22 sets a plurality of limited fields of view to limit the area to be irradiated with a focused ion beam, and then irradiates a focused ion beam to destroy the sample piece Q while sequentially switching the plurality of limited fields of view one after another.

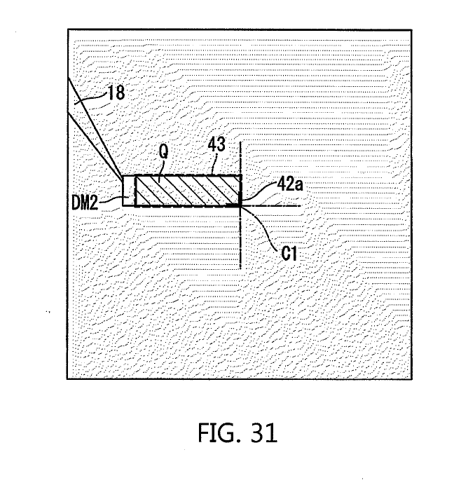

For example, the computer 22 sets a first limited field of view 43 that starts from the center position C1 of the field of view of the focused ion beam and within which the sample piece Q is disposed but the tip of the needle 18 is not disposed, and irradiates a current ion beam having a relatively large current to an irradiation region including the first limited field of view 43. FIG. 31 is a diagram illustrating an example of the first limited field of view 43 (drawn in a bold dashed line) that is set to be spaced, in the direction of the needle 18, from the center position C1 of the field of view in the image data formed by a focused ion beam. The computer 22 may set the first field of view 43 having a size such that the sample piece Q falls within the first field of view but the tip of the needle 18 does not fall within the first field of view, based on pre-stored data of dimensions of the sample piece Q.

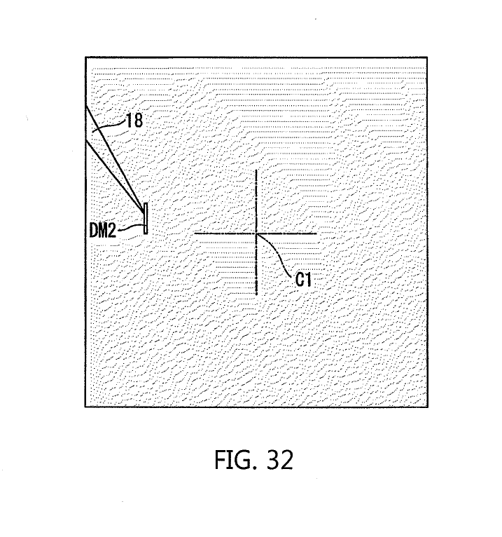

Next, for example, the computer 22 sets a second limited field of view 44 that is spaced, in the direction of the needle 18, from the center position C1 of the field of view of a focused ion beam and within which the tip of the needle 18 is not disposed, and irradiates a focused ion beam having a relatively small current to an irradiation region including the second field of view 44. FIG. 32 is a diagram illustrating an example of the second limited field of view 44 (drawn in a bold dashed line), which is set at a position spaced from the center position C1 of the field of view, in the direction of the needle 18, by a predetermined distance, in the image data formed by the focused ion beam. The computer 22 sets the second field of view 44 that has a size smaller than the first limited field of view 43 and which includes a region relatively close the needle 18 as compared with the first limited view of view, with reference to the center position C1 of the field of view, but which does not includes the tip of the needle 18.

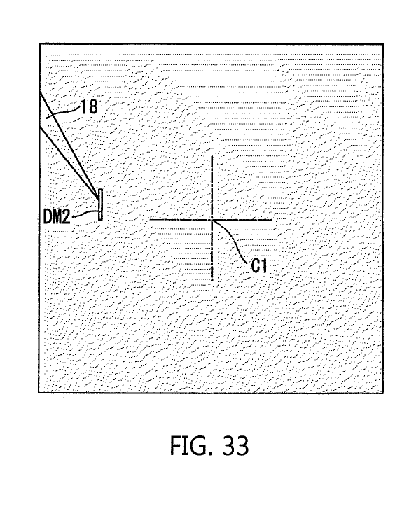

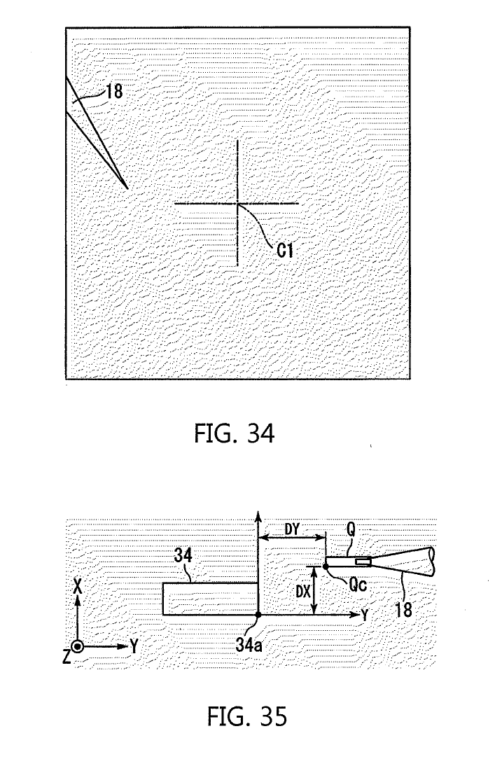

FIGS. 33 and 34 are views illustrating examples of the tip of the needle 18 after the sample piece Q is destroyed by a focused ion beam that is irradiated using the first field of view 43 and the second field of view 44, in the image data formed by the focused ion beam. FIG. 33 is a diagram illustrating a state in which a residue of the deposition film DM 2 remains on the tip of the needle 18, and FIG. 34 is a diagram illustrating a state in which no residue of the deposition film DM 2 remains on the tip of the needle 18.

After performing the destroying processing in Step S380, the computer 22 may perform cleaning of the needle 18 as necessary, in a manner described in a first modification described below even in the case of proceeding to Step S280 after performing the error processing process. As described below, the computer 22 performs the cleaning of the needle 18, for example, when the size of the residue of the deposition film DM2 remaining at the tip of the needle 18 is larger than a predetermined size.

Although it is described above that the computer 22 sets the first limited field of view 43 and the second limited field of view 44, based on the stored data of the dimensions of the sample piece Q, the present invention is not limited thereto. For example, the computer 22 grasps the size of the sample piece Q, based on the edge of the sample piece Q, which is extracted from the image data formed by a focused ion beam, and may set the first limited field of view 43 and the second limited field of view 44 using the size of the sample piece Q. Further, the computer 22 may set the first field of view 43 and the second field of view 44 while correcting the data of the dimensions of the sample piece Q previously recorded, using information on the size of the sample piece Q, which is grasped on the basis of the edge extracted from the image of the sample piece Q.

Further, the limited fields of view set by the computer 22 are not limited to the first limited field of view 43 and the second limited field of view 44 but the computer 22 may set three or more limited fields of view. The focused ion beam is irradiated while the limited fields of view are switched in order from a limited field of view set at a region relatively far from the needle 18 to a limited field of view set at a region relatively close to the needle 18.

Thus, the series of automatic sampling operations is completed.

It should be noted that the above-described flow from the start to the end is merely an example, and some steps may be replaced or skipped as long as it becomes no obstacle to the overall processing.

By continuously performing the above-described flow from the start to the end, the computer 22 can perform the sampling operation unattended. With the method described above, it is possible to repeatedly perform sampling without replacing the needle 18. That is, it is possible to continuously sample a large number of sample pieces Q using the same needle 18.

Thereby, when separating and extracting the sample pieces Q from the sample S, the charged particle beam apparatus 10 can repeatedly use the same needle without reshaping the needle 18 or without replacing the needle 18. That is, it is possible to automatically prepare a large number of sample pieces Q from one sample S. Sampling can be carried out without manual operation of an operator as in the past.

As described above, in the case of using the charged particle beam apparatus 10 according to the embodiment of the present invention, when an abnormality occurs when a sample piece Q held by the needle 18 is transferred to a columnar portion 34 of a sample piece holder P, the sample piece Q is destroyed. Therefore, the operation can properly proceed to the next processing such as sampling of a new sample piece Q. When it is difficult to extract an edge of the columnar portion 34 at the time of determining whether the shape of the columnar portion 34 is normal or abnormal from the image, although in the case where an abnormality, for example, an event in which template matching of the columnar portion 34 cannot be accurately performed due to deformation, breakage, or missing of the columnar portion 34, occurs, it is possible to prevent process shifting from being interrupted. Therefore, it is possible to continuously and automatically perform the sampling operation of extracting the sample piece Q formed by processing the sample S with a focused ion beam and transferring the formed sample piece Q to the sample piece holder P.

Further, since the computer 22 sets a plurality of limited fields of view for limiting a region to be irradiated with a focused ion beam when the sample piece Q is destroyed by the focused ion beam irradiated thereto, the computer 22 can switch the plurality of fields of view to make a stepwise approach to the needle 18, and to prevent the needle 18 from being damaged by the focused ion beam.

Further, the computer 22 sets the limited fields of view such that a limited field of view relatively close to the needle 18, among the plurality of limited fields of view, is smaller than a limited field of view relatively far from the needle 18 and a beam intensity of a focused ion beam with respect to a limited field of view relatively close to the needle 18 is weaker than a beam intensity of a focused ion beam with respect to a limited field of view relatively far from the needle 18, thereby preventing the needle 18 from being damaged.

Further, the computer 22 sets a plurality of limited fields of view such that the needle 18 is not disposed, based on the reference position of the sample piece Q, and known information or the size of the sample piece Q acquired from the image. Therefore, it is possible to prevent the needle 18 from being damaged by a focused ion beam irradiated thereto.

Furthermore, when the sample piece Q is destroyed by a focused ion beam irradiated thereto, the computer 22 aligns the reference positions such as the positions of the edge 42a and 42b of the sample piece Q with the center positions C1 and C2 of the fields of view, thereby facilitating observation with a high magnification, and other processing.

Furthermore, the computer 22 controls the focused ion beam irradiation optical system 14, the electron beam irradiation optical system 15, the stage driving mechanism 13, the needle The driving mechanism 19, and the gas supply unit 17, based on the actually acquired templates of at least the sample piece holder P, the needle 18, and the sample piece Q. Therefore, the operation of transferring the sample piece Q to the sample piece holder P can be appropriately automated.

Furthermore, since the templates are created from secondary electron images or absorption current images acquired by scanning a charged particle beam in a state where there is no structure in the backgrounds of at least the sample piece holder P, the needle 18, and the sample piece Q, reliability of the templates can be improved. Thereby, the accuracy of template matching using the templates can be improved, and the sample piece Q can be accurately transferred to the sample piece holder P, based on the position information obtained through the template matching.

Although it is instructed that no structure exists in the backgrounds of at least the sample piece holder P, the needle 18, and the sample piece Q, when the instruction is not fulfilled, the positions of at least the sample piece holder P, the needle 18, and the sample piece Q are initialized. Therefore, each of the driving mechanisms 13 and 19 can be returned to a normal state.

Furthermore, since the templates are created for each of a plurality of postures of the sample piece Q when the sample piece Q is transferred to the sample piece holder P, the positional accuracy at the time of transferring the sample piece Q can be improved.

Furthermore, since the distances among the sample piece holder P, the needle 18, and the sample piece Q are measured based on template matching using the templates of at least the sample piece holder P, the needle 18, and the sample piece Q, the positional accuracy at the time of transferring the sample piece can be further improved.

Furthermore, when it is impossible to extract an edge of a predetermined region in each of the image data of the sample piece holder P, the needle 18, and the sample piece Q, image data is obtained again. Therefore, the templates can be accurately created.

Since the sample piece Q is finally moved to a predetermined position within the sample piece holder P by being moved only within a plane that is in parallel with the surface of the stage 12, the sample piece Q can be properly transferred.

Furthermore, since the sample piece Q held on the needle 18 is shaped before the template thereof is prepared, the accuracy of edge extraction at the time of template formation can be improved, and the shape of the sample piece Q, which is suitable for finish processing to be performed later, can be obtained. Furthermore, since the position for the shaping process is set depending on the distance from the needle 18, it is possible to perform the shaping process with high accuracy.

Furthermore, when the needle 18 holding the sample piece Q is rotated so as to be in a predetermined posture, the positional deviation of the needle 18 can be corrected through eccentricity correction.

Further, with the charged particle beam apparatus 10 according to the embodiment of the present invention, the computer 22 can detect the relative position of the needle 18 with respect to the reference mark Ref when the sample piece Q is formed, and grasp the positional relationship of the needle 18 with respect to the sample piece Q 18. The computer 22 continuously detects the relative position of the needle 18 with respect to the sample piece Q so as to drive the needle 18 in a three-dimensional space, appropriately, i.e., by preventing the needle 18 from coming into contact with other members or equipment.

Furthermore, by using the image data acquired from at least two different directions, the computer 22 can accurately grasp the position of the needle 18 in a three-dimensional space. As a result, the computer 22 can appropriately three-dimensionally drive the needle 18.

Furthermore, since the computer 22 uses image data actually generated just before the movement of the needle 18 as templates (reference image data), template matching can be performed with high matching accuracy regardless of the shape of the needle 18. Thereby, the computer 22 can accurately grasp the position of the needle 18 in a three-dimensional space, and can appropriately drive the needle 18 in the three-dimensional space. Furthermore, the computer 22 evacuates the stage 12 and acquires image data or absorption current image data in a state in which there is no complicated structure in the background of the needle 18. Therefore, the computer 22 can acquire a template from which the shape of the needle 18 can be clearly grasped without influence of the background.

Further, since the needle 18 and the sample piece Q are connected by the deposition film rather than being in a direct contact with each other, the computer 22 can prevent the needle 18 from being cut when the needle 18 and the sample piece Q are separated in a later process. Furthermore, even when the needle 18 vibrates, it is possible to suppress the vibration of the needle 18 from being transmitted to the sample piece Q. Furthermore, even when the movement of the sample piece Q occurs due to the creep phenomenon of the sample S, excessive strain between the needle 18 and the sample piece Q can be suppressed.

Furthermore, in the case where the sample S and the sample piece Q are disconnected through a sputtering process, i.e., irradiation of a focused ion beam, the computer 22 determines whether or not the cutting is actually completed by detecting electrical conduction between the sample S and the needle 18.

Furthermore, since the computer 22 informs an operator of the state in which the separation between the sample S and the sample piece Q is not completed, even in the case where the execution of the processes that are to be automatically performed is stopped, the cause of this interruption can be easily recognized by the operator.

Further, when electrical conduction between the sample piece S and the needle 18 is detected, the computer 22 determines that disconnection between the sample piece S and the sample piece Q is not actually completed, and the disconnection between the sample piece Q and the needle 18 is made in preparation for subsequent driving of the needle 18 such as evacuation of the needle 18. As a result, the computer 22 can prevent troubles such as displacement of the sample S or breakage of the needle 18 attributable to driving of the needle 18.

Further, the computer 22 may drive needle 18 after confirming that disconnection between the sample A and the sample piece Q is actually completed by detecting electrical conduction or non-conduction between the sample piece Q and the needle 18. Thereby, the computer 22 can prevent occurrence of troubles such as breakage of the needle 18 or the sample piece Q or positional deviation of the sample piece Q, attributable to the driving of the needle 18.

Further, since the computer 22 uses actual image data as a template of the needle 18 connected to the sample piece Q, template matching is performed with high matching accuracy regardless of the shape of the needle 18 connected to the sample piece Q. Thereby, the computer 22 can accurately grasp the position of the needle 18 connected to the sample piece Q in a three-dimensional space, and can appropriately drive the needle 18 and the sample piece Q in the three-dimensional space.

Further, since the computer 22 obtains the positions of a plurality of columnar portions 34 constituting a sample base 33, using the template of the known sample base 33, it is possible to check whether there is a sample base 33 that is in a proper state prior to the driving of the needle 18.

Further, the computer 22 can indirectly and accurately determine whether the needle 18 and the sample piece Q reach the vicinity of the movement target position, by detecting a change in the absorption current before and after the needle 18 connected to the sample piece Q reaches the irradiation region. Thereby, the computer 22 can stop the needle 18 and the sample piece Q without a risk that the needle 18 and the sample piece Q come into contact with other members such as the sample base 33 existing at the movement target position, and can prevent occurrence of troubles such as damage caused by the contact.

Furthermore, in the case where the sample piece Q and the sample base 33 are connected by the deposition film, the computer 22 detects electrical conduction between the sample base 33 and the needle 18. Therefore, it is possible to accurately check whether the connection between the sample piece Q and the sample base 33 is completed.

Further, the computer 22 can disconnect the sample piece Q and the needle from each other after detecting electrical conduction between the sample base 33 and the needle 18 and after confirming that connection between the sample base 33 and the sample piece Q is actually completed.

In addition, by matching the actual shape of the needle 18 with an ideal reference shape, the computer 22 can easily recognize the needle 18 through pattern matching when driving the needle 18 in a three-dimensional space, and can precisely detect the position of the needle 18 in the three-dimensional space.

Hereinafter, a first modification of the above-described embodiment will be described.

In the above embodiment, the needle 18 is not irradiated with a focused ion beam, so that the needle 18 is not likely to be deformed or reduced. Therefore, shaping or replacing of the needle 18 is not necessarily performed. However, the computer 22 may perform a removal process (also referred to as cleaning of the needle 18) of removing a carbon deposition film attached to the tip of the needle 18 at appropriate timing, for example, whenever a predetermined number of samplings are performed, in the case where the automatic sampling operation is repeatedly performed. For example, the cleaning may be performed once for every 10 automatic samplings. Hereinafter, a method of determining the timing for the cleaning of the needle 18 will be described.

As a first method, a secondary electron image of the tip of the needle is acquired through irradiation of an electron beam periodically or before automatic sampling is performed, at a position at which no complex structure exists in the background of the needle. With the use of the secondary electron image, even a carbon deposition film attached to the tip of the needle can be clearly recognized. The secondary electron image is stored in the computer 22.

Next, with the needle 18 being stationed, an absorption current image of the needle 18 is acquired using the same field of view and the same observation magnification as those used to acquire the secondary electron image. In the absorption current image, the carbon deposition film cannot be recognized but only the shape of the needle 18 can be recognized. This absorption current image is also stored in the computer 22.

Here, by subtracting the absorption current image from the secondary electron image, the needle 18 is erased, and the shape of the carbon deposition film protruding from the tip of the needle becomes manifested. When the area of the manifested carbon deposition film exceeds a predetermined area, the needle 18 is not cut but the carbon deposition film is cleaned away through irradiation of a focused ion beam. Note that it is not necessary to remove the carbon deposition film when its area is equal to or smaller than the predetermined area.

Next, as a second method, instead of using the area of the manifested carbon deposition film to determine timing for cleaning, when the length of the carbon deposition film, i.e., a length thereof in the axial direction (longitudinal direction) of the needle 18 is greater than a predetermined value, it may be determined that it is time to perform cleaning of the needle 18.

Furthermore, as a third method, the image coordinates of the tip of the carbon deposition film on the secondary electron image stored in the computer are recorded. In addition, the image coordinates of the tip of the needle on the absorption current image stored in the computer 22 are also recorded. Here, the length of the carbon deposition film can be calculated from the coordinates of the tip of the carbon deposition film and the coordinates of the tip of the needle 18. When the length is greater than a predetermined value, it may be determined that it is time to perform cleaning of the needle 18.

Further, as a fourth method, a template of an optimal needle tip shape including a carbon deposition film is created in advance, and the template is superimposed on the secondary electron image of the tip of the needle after sampling is repeated a plurality of times. Portions protruding from the template may be deleted by a focused ion beam.

Further, as a fifth method, instead of using the area of the manifested carbon deposition film to determine timing for cleaning, when the thickness of the carbon deposition film at the tip of the needle 18 exceeds a predetermined thickness, it is determined that it is time to perform cleaning of the needle 18.

The cleaning may be performed, for example, immediately after Step S280 in FIG. 20.

The cleaning is performed according to the above-mentioned method and the like. Meanwhile, the needle can be replaced at a predetermined time, when a predetermined shape cannot be obtained even after the cleaning is performed, or when the cleaning cannot be performed within a predetermined time. Even after the needle 18 is replaced, the above processing flow is not changed but a process of preserving the shape of the tip of the needle is performed as described above.

Hereinafter, a second modification of the above-described embodiment will be described.

Although the computer 22 extracts the edges 42a and 42b of the sample piece Q in the error processing process in the embodiment described above, the extracted portions are not limited thereto. The computer 22 may extract portions other than the edges 42a and 42b of the sample piece Q and align the extracted portions with the center position C1 of the field of view a focused ion beam and the center position C2 of the field of view of an electron beam.

For example, the computer 22 grasps the reference position such as the center position of the sample piece Q, based on the template matching using the previously prepared templates and the information of the size of the sample piece Q, and aligns this reference position with the center position C1 of the field of view of the focused ion and with the center position C2 of the field of view of the electron beam.

Hereinafter, a third modification of the above-described embodiment will be described.

Although in the above embodiment, the computer 22 destroys the sample piece Q in the error processing process by irradiating the sample piece Q connected to the needle 18 with the focused ion beam in the sample piece destroying process (Step S380), a method of destroying the sample piece is not limited to this.

The computer 22 may drive the needle driving mechanism 19 such that the sample piece Q connected to the needle 18 collides with an obstacle inside the sample chamber 11, whereby the deposition film DM 2 connecting the needle 18 and the sample piece Q is ruptured and thus the sample piece Q can be separated from the needle 18. The obstacle inside the sample chamber 11 is, for example, the sample S fixed to the stage 12, the sample piece holder P held by the holder fixing base 12a, or the like. Even after the deposition film DM2 is ruptured, the computer 22 may perform cleaning of the needle 18 as necessary, as in the above-described first modification. Note that the sample piece Q separated from the needle 18 is discharged outside the sample chamber 11, for example, by an air exhauster (not shown) that exhausts air inside the sample chamber 11.

Hereinafter, a fourth modification of the above-described embodiment will be described.

Although, in the above-described embodiment, the needle driving mechanism 19 is unitarily provided with the stage 12, the present invention is not limited thereto. The needle driving mechanism 19 may be provided independently of the stage 12. The needle driving mechanism 19 may be provided independently of tilt-driving of the stage 12 or the like by being fixed to the sample chamber 11 or the like, for example.

Hereinafter, a fifth modification of the above-described embodiment will be described.

In the above-described embodiment, the focused ion beam irradiation optical system 14 has the optical axis aligned with the vertical direction, and the electron beam irradiation optical system 15 has the optical axis inclined with respect to the vertical direction. However, the present invention is not limited thereto. For example, the focused ion beam irradiation optical system 14 may have the optical axis inclined with respect to the vertical direction, and the electron beam irradiation optical system 15 may have the optical axis aligned with the vertical direction.

Hereinafter, a sixth modification of the above-described embodiment will be described.

Although, in the above-described embodiment, the charged particle beam irradiation optical system is composed of the focused ion beam irradiation optical system 14 and the electron beam irradiation optical system 15 to irradiate a target with two different beams, the present invention is not limited thereto. For example, the charged particle beam irradiation optical system may not include the electron beam irradiation optical system 15 but include only the focused ion beam irradiation optical system 14 arranged in the vertical direction. Ions used in this case are negatively charged ions.

In the above-described embodiment, in the above-described several steps, the sample piece holder P, the needle 18, the sample piece Q, and the like are irradiated with the electron beam and the focused ion beam irradiated from different directions, and the images formed by the electron beam and the focused ion beam are acquired. In addition, the positions of the sample piece holder P, the needle 18, the sample piece Q, etc. and the positional relationships among them are grasped. However, only the focused ion beam irradiation optical system 14 may be mounted and only the image of the focused ion beam may be acquired. Herein below, this example will be described below.

For example, when grasping the positional relationship between the sample piece holder P and the sample piece Q in Step S220, in the case where the stage 12 is aligned in the horizontal direction and the case where the stage 12 is inclined at a predetermined angle from the horizontal direction, an image of a focused ion beam is acquired in a state in which both the sample piece holder P and the sample piece Q are within in the same field of view, and the three dimensional positional relationship between the sample piece holder P and the sample piece Q can be grasped from both images. As described above, since the needle driving mechanism 19 can integrally move with the stage 12 in the horizontal direction and the vertical direction, and can be tilted, the relative positional relationship between the sample piece holder P and the sample piece Q is maintained regardless of whether the stage 12 is in a horizontal posture or an inclined posture. Therefore, even when the charged particle beam irradiation optical system is composed of only one optical system (the focused ion beam irradiation optical systems 14), it is possible to observe and process the sample piece Q from two different directions.

Similarly, the registration of the image data of the sample piece holder P in Step S020, the recognition of the position of the needle in Step S040, the acquisition of the template (reference image) of the needle in Step S050, the acquisition of the reference image of the needle 18 connected to the sample piece Q in Step S170, the recognition of the attachment position of the sample piece Q in Step S210, and the stopping of the needle movement in Step S250 may be performed in the same manner.

Also when the sample piece Q and the sample piece holder P are connected in Step S250, when the stage 12 is in a horizontal posture, the sample piece Q is connected to the sample piece holder P by forming a deposition film on the upper end surface of the sample piece Q. Furthermore, since it is possible to form a deposition film from different directions by tiling the stage 12, a reliable connection between the sample piece Q and the sample piece holder P can be made.

Hereinafter, a seventh modification of the above-described embodiment will be described.

Although, in the embodiment described above, the computer 22 automatically performs the series of processes from Step S010 to Step S280 as the automatic sampling operation, the present invention is not limited thereto. The computer 22 may replace processing of at least one step among the steps from Step S010 to Step S280 with manual processing performed by an operator.

Further, when performing the automatic sampling operation with respect to a plurality of sample pieces Q, each time one of the plurality of sample pieces Q to be immediately extracted is formed on a sample S, the computer 22 may perform the automatic sampling operation with respect to the corresponding sample piece Q that is to be immediately extracted. The computer 22 may continuously perform the automatic sampling operation with respect each of the plurality of sample pieces Q which are to be immediately extracted, after all of the sample pieces Q are formed on the sample.

Hereinafter, an eighth modification of the above-described embodiment will be described.

Although, in the embodiment described above, the computer 22 obtains the position of the columnar portion 34 using the known template of the columnar portion 34, the reference pattern that is created in advance from the image data of the actual columnar portion 34 may be used as the template. Further, the computer 22 may use a pattern created at the time of performing an automatic process of forming the sample base 33 as the template.

Further, in the embodiment described above, the computer 22 may grasp the relative positional relationship between the sample base 33 and the needle 18, using the reference mark Ref formed through irradiation of the charged particle beam at the time of forming the columnar portion 34. The computer 22 sequentially detects the relative position of the needle 18 with respect to the position of the sample base 33, thereby driving the needle 18 in a three-dimensional space, appropriately, i.e., by preventing the needle 18 from coming into contact with other members or equipment.

Hereinafter, a ninth modification of the above-described embodiment will be described.

In the above-described embodiment, the processing of from Step S220 to Step S250 for connecting the sample piece Q to the sample piece holder P may be alternatively performed in a manner described below. In other words, the positional relationship (distance) between the columnar portion 34 of the sample piece holder P and the sample piece Q are obtained from the images thereof, and the needle driving mechanism 19 is operated such that the calculated distance between the columnar portion 34 and the sample piece Q equals a target value.

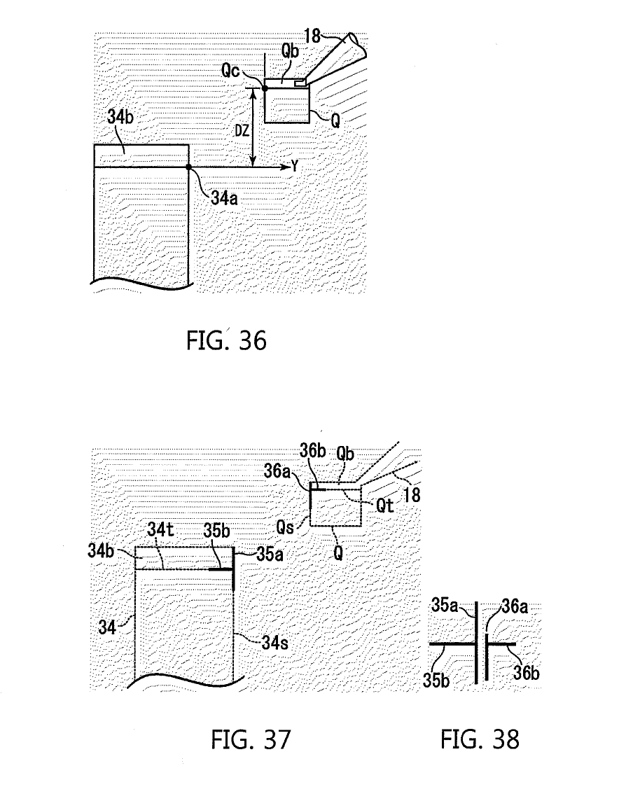

In Step S220, the computer 22 recognizes the positional relationships among the needle 18, the sample piece Q, and the columnar portion 34 from secondary particle image data or absorption current image data thereof formed by an electron beam and a focused ion beam. FIGS. 35 and 36 are diagrams schematically illustrating the positional relationship between the columnar portion 34 and the sample piece Q. FIG. 35 is based on an image formed by a focused ion beam and FIG. 36 is based on an image formed by an electron beam. From these figures, the relative positional relationship between the columnar portion 34 and the sample piece Q is measured. As illustrated in FIG. 35, orthogonal three-axis coordinates (coordinates different from the three-axis coordinates of the stage 12) are set with the origin at one corner (for example, the side surface 34a) of the columnar portion 34, and distances DX and DY are measured from the image of FIG. 35 as the distance between the side surface 34a (origin) of the columnar portion 34 and the reference point Qc of the sample piece Q.

A distance DZ is obtained from the image of FIG. 35. However, when it is assumed that the stage is inclined by an angle θ (0°<θ≤90°) with respect to the optical axis of the electron beam and the optical axis (vertical direction) of the focused ion beam, the actual distance between the columnar portion 34 and the sample piece Q in the Z axis direction is DZ/sin θ.

Next, the positional relationship between the columnar portion 34 and a movement stop position of the sample piece Q will be described with reference to FIGS. 35 and 36.

The upper end surface (end face) 34b of the columnar portion 34 and the upper end surface Qb of the sample piece Q are flush with each other and one side surface of the columnar portion 34 and the cross-sectional surface of the sample piece Q are flush with each other, and the columnar portion 34 and the sample piece Q are arranged to have a gap of about 0.5 μm therebetween. That is, by operating the needle driving mechanism 19 such that DX=0, DY=0.5 μm, and DZ=0, it is possible to make the sample piece Q reach a target stop position.

In the construction in which the optical axis of the focused ion beam and the optical axis of the electron beam are perpendicular to each other (θ=90°), the distance DZ between the columnar portion 34 and the sample piece Q, which is measured by the electron beam, is an actual distance between the columnar portion 34 and the sample piece Q.

Hereinafter, a tenth modification of the above-described embodiment will be described.

In the above-described embodiment, the needle driving mechanism 19 is operated in Step S230 such that the distance between the columnar portion 34 and the sample piece Q measured from the image of the needle 18 becomes a target value.

The processing of from Step S220 to Step S250 for connecting the sample piece Q to the sample piece holder P in the above-described embodiment may be alternatively performed in a manner described below. In other words, the attachment position at which the sample piece Q is attached to the columnar portion 34 of the sample piece holder P is determined in advance by using the templates, the image of the sample piece Q is aligned with the attachment position through pattern matching, and the needle driving mechanism 19 is operated.

The positional relationship between the movement stop position of the sample piece Q and the columnar portion 34 will be described. The positional relationship is such that the upper end surface 34b of the columnar portion 34 and the upper end surface Qb of the sample piece Q are made to be flush with each other, one side surface of the columnar portion 34 and the cross-sectional surface of the sample piece Q are flush with each other, and there is a gap of 0.5 □μm between the columnar portion 34 and the sample piece Q. The template may be created by extracting the outlines (edges) from an actual secondary electron image or actual absorption current image data of the sample piece holder P or the needle 18 to which sample piece Q is fixed. The template may be a line drawing, a design drawing, or a CAD drawing.

By displaying the columnar portion 34 within the created template to be superimposed on the images of the columnar portion 34 formed in real time by an electron beam and a focused ion beam, and by instructing the needle driving mechanism 19 to operate, the sample piece Q is moved to the stop position of the sample piece Q on the template in Step S230. In Step S240, it is confirmed that images formed by the electron beam and the focused ion beam in real time overlap the stop position of the sample piece Q on the predetermined template, and operation of the needle driving mechanism 19 is stopped. In this way, the sample piece Q can be accurately moved to be in the predetermined positional relationship with the columnar portion 34 at the predetermined stop position.

Further, as another embodiment of the processing of from Step S230 to Step S250, the following may be performed. A line drawing of the edge portion extracted from the secondary particle image or the absorption current image data is limited to only a minimum necessary portion required for positioning the columnar portion 34 and the sample piece Q. FIG. 37 illustrates an example thereof, and the columnar portion 34, the sample piece Q, the outline (drawn in a dotted line), and the extracted edge (drawn in a bold solid line) are illustrated. The to-be-extracted edges of the sample piece Q and the columnar portion 34 are edges 34s and Qs facing each other and parts of edges 34t and Qt at the respective end surfaces 34b and Qb of the columnar portion 34 and the sample piece Q. As the edges of the columnar portion 34, line segments 35a and 35b are sufficient. As the edges of the sample piece Q, line segments 36a and 36b are sufficient. Each line segment is a portion of each edge. With these line segments, for example, a T-shaped template can be created. The stage driving mechanism 13 and the needle driving mechanism 19 are operated to move the corresponding templates thereof. Based on these templates 35a, 35b, 36a, and 36b, the spacing between the columnar portion 34 and the sample piece Q, and the parallelisms and the heights of the columnar portion 34 and the sample piece Q can be grasped from the mutual positional relationship. Therefore, the columnar portion 34 and the sample piece Q can be easily aligned. FIG. 38 illustrates a positional relationship between the templates, which corresponds to the predetermined positional relationship between the columnar portion 34 and the sample piece Q, in which the line segments 35a and 36a are parallel to each other at a predetermined interval, and the line segments 35b and 36b are on a straight line. At least one of the stage driving mechanism 13 and the needle driving mechanism 19 is operated and the operated driving mechanism stops when the templates have the positional relationship illustrated in FIG. 38.

In this way, the templates can be used for precise alignment after it is confirmed that the sample piece Q has approached a predetermined columnar portion 34.

Next, as an eleventh modification of the above-described embodiment, another example of the processing of from S220 to S250 will be described.

In the above-described embodiment, the needle 18 is moved in Step S230. When the sample piece Q that has just undergone Step S230 is deviated from a target position by a great distance, the operation described below may be performed.

In Step S220, it is desirable that the sample piece Q is positioned, before the movement, in a region of Y>0 and Z>0 in a three-dimensional rectangular coordinate system having the origin that coincides with the origin of each columnar portion 34. This arrangement is desirable in terms of minimizing the possibility of collision of the sample piece Q with the columnar portion 34 during the movement of the needle 18. Thereby, the sample piece Q can be safely and quickly moved to the target position by simultaneously operating X, Y, and Z driving portions of the needle driving mechanism 19. Meanwhile, when the sample piece Q is positioned, before the movement, in a region of Y<0, when the X, Y, Z driving portions of the needle driving mechanism 19 are simultaneously operated to move the sample piece Q toward the stop position thereof, the sample piece Q is highly likely to collide with the columnar portion 34. Therefore, when the sample piece Q is positioned in the region of Y<0 in Step S220, the needle 18 is guided to the target position avoiding a route on which the columnar portion 34 is disposed. Specifically, the sample piece Q is first moved to a region of Y>0 by driving only the Y driving portion of the needle driving mechanism 19 whereby the sample piece Q reaches to a predetermined position (for example, a position spaced from the columnar portion 34 by a distance that is twice, three times, five times, or 10 times the width of the target columnar portion 34, etc.), and is then moved toward the final stop position by simultaneously operating the X, Y, and Z driving portions of the needle driving mechanism. In this way, the sample piece Q can be safely and quickly moved while avoiding collision with the columnar portion 34. Meanwhile, when it is confirmed that the X coordinates of the sample piece Q and the columnar portion 34 are the same and the Z coordinate of the sample piece Q is lower than the Z coordinate of the upper end of the columnar portion (Z<0), from the electron beam image and/or the focused ion beam image, the sample piece Q is first moved to a region of Z>0 (for example, the position of Z=2 μm, 3 μm, 5 μm, or 10 μm) and then moved to a predetermined position in the region of Y>0, and finally moved toward the final stop position by simultaneously operating of the X, Y, and Z driving portions of the needle driving mechanism. By moving the sample piece Q in this manner, the sample piece Q can reach the target position without colliding with the columnar portion 34.

Next, a twelfth modification of the above-described embodiment will be described.

In the charged particle beam apparatus 10 according to the present invention, the needle 18 can be pivoted by the needle driving mechanism 19. In the above embodiment, the most basic sampling procedure in which pivoting (axial rotation) of the needle 18 is not used except for the needle trimming has been described. However, in the twelfth modification, an embodiment using axial rotation of the needle 18 will be described.

Since the computer 22 can pivot the needle 18 by operating the needle driving mechanism 19, the computer 22 can control the posture of the sample piece Q as necessary. The computer 22 rotates the sample piece Q extracted from the sample S and fixes the sample piece Q in a state in which the positions of the upper and lower ends and the positions of the right and left ends are adjusted, to the sample piece holder P. The computer 22 fixes the sample piece Q so that the surface of the sample piece Q, which corresponds to the original surface of the sample S from which the sample piece Q is extracted, is parallel or perpendicular to the cross-sectional surface of the columnar portion 34. Thereby, the computer 22 can secure the posture of the sample piece Q, which is suitable for finish processing to be performed later, and reduce the curtain effect or the like occurring in a finish process of lamellating the sample piece Q. The term “curtain effect” refers to a stripe pattern appearing in a direction in which the focused ion beam is irradiated, and results in erroneous interpretation during electron microscopic observation of a processed sample piece. The computer 22 performs eccentricity correction when rotating the needle, thereby correcting the rotation so that the sample piece Q falls within the actual field of view.

Further, the computer 22 shapes the sample piece Q by irradiating the sample piece Q with a focused ion beam as necessary. In particular, it is desirable that the sample piece Q is shaped so that the end face thereof in contact with the columnar portion 34 is substantially parallel to the end face of the columnar portion 34 after the sample piece Q is shaped. The computer 22 performs a shaping process such as cutting a part of the sample piece Q before creating a template to be described later. The computer 22 sets a processing position for the shaping process with reference to the distance from the needle 18. Thereby, the computer 22 facilitates extraction of the edge from the template to be described later, and secures the shape of the sample piece Q suitable for the finish processing to be performed later.

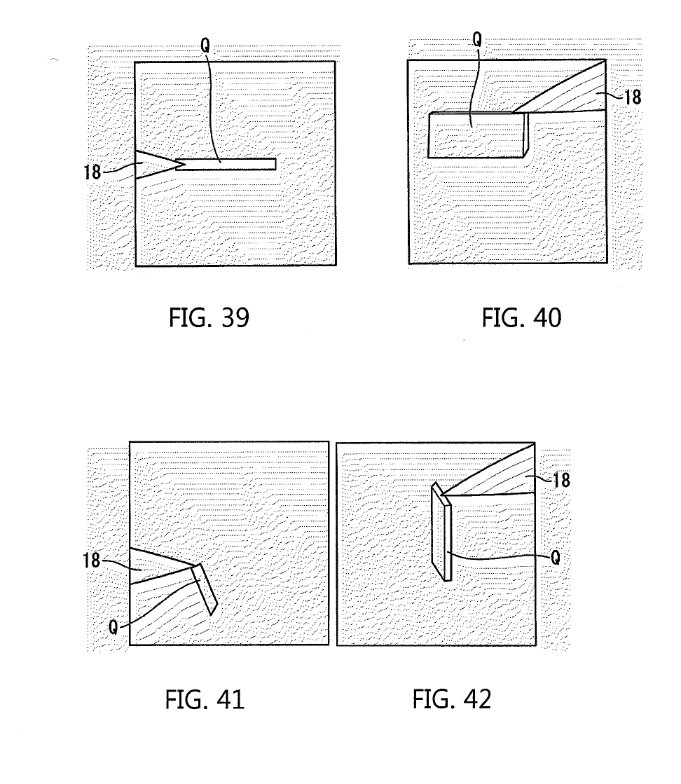

Following Step S150 described above, in regards to the posture control, the computer 22 first drives the needle 18 by using the needle driving mechanism 19, and rotates the needle 18 by an angle corresponding to a posture control mode so that the sample piece Q has a predetermined posture. Here, the posture control mode is a mode in which the sample piece Q is controlled to have a predetermined posture. The needle 18 approaches the sample piece Q while having a predetermined angle with respect to the sample piece Q, and rotates the needle 18 to which the sample piece Q is connected by a predetermined angle, thereby controlling the posture of the sample piece Q. The computer 22 performs eccentricity correction when rotating the needle 18. FIG. 39 to FIG. 44 illustrate these states, and are diagrams illustrating the needle 18 connected to the sample piece Q in a plurality of (for example, three) approach modes.

FIGS. 39 and 40 are diagrams illustrating the states of the needle 18 connected to a sample piece Q in an approach mode in which a rotation angle of the needle 19 is 0°. FIG. 39 illustrates the state of the needle 18 connected to the sample piece Q, in image data formed by a focused ion beam of the charged particle beam apparatus 10 according to the embodiment of the present invention, and FIG. 40 illustrates the state of the needle 18 connected to the sample piece in image data formed by an electron beam. In the approach mode in which the rotation angle of the needle 19 is 0°, the computer 22 sets a posture state suitable for transferring the sample piece Q to the sample piece holder P without rotating the needle 18.

FIGS. 41 and 42 are diagrams illustrating the states of the needle 18 in an approach mode in which the rotation angle of the needle 19 is 90°. FIG. 41 illustrates the state of the needle 18 connected to the sample piece Q and rotated by 90° in image data formed by a focused ion beam of the charged particle beam apparatus 10 according to the embodiment of the present invention, and FIG. 42 illustrates the state of the needle 18 connected to the sample piece and rotated by 90° in image data formed by an electron beam. In the approach mode in which the needle is rotated by 90°, the computer 22 sets a posture state suitable for transferring the sample piece Q to the sample piece holder P in a state where the needle 18 is rotated by 90°.

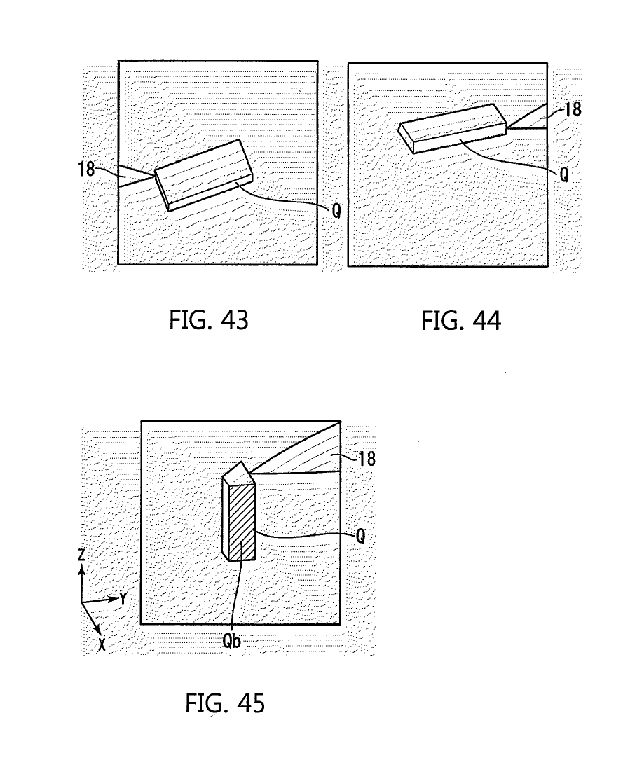

FIGS. 43 and 44 are diagrams illustrating the states of the needle 18 connected to the sample piece Q in an approach mode in which the rotation angle of the needle 18 is 180°. FIG. 43 illustrates the state of the needle 16 connected to the sample piece Q and rotated by 180° in image data formed by a focused ion beam of the charged particle beam apparatus 10 according to the embodiment of the present invention and FIG. 44 illustrates the state of the needle 18 connected to the sample piece Q and rotated by 180° in image data formed by an electron beam. In the approach mode in which the needle 18 is rotated by a rotation angle of 180°°, the computer 22 sets a posture state suitable for transferring the sample piece Q to the sample piece holder P in a state where the needle 18 is rotated by 180°.

The relative connection posture between the needle 18 and the sample piece Q is set to a connection posture suitable for each approach mode when the needle 18 is connected to the sample piece Q in the sample piece pickup process described above.

Next, a thirteenth modification of the above-described embodiment will be described.

In the thirteenth modification, an embodiment in which a planar sample piece is manufactured by utilizing the fact that the needle 18 can be rotated by the needle driving mechanism 19 in the charged particle beam device 10 will be described.

The term “planar sample piece (lamella)” refers to a sample piece that is produced by lamellating a sample piece separated and extracted from an original sample and is formed to be parallel to the surface of the original sample in order to observe a surface inside the original sample.

FIG. 45 is a diagram illustrating a state in which a separated and extracted sample piece Q is fixed to the tip of the needle 18. FIG. 45 schematically illustrates an image formed by an electron beam. When fixing the needle 18 to the sample piece Q, the sample piece Q is fixed using the method illustrated in FIGS. 5 to 8. When the rotation axis of the needle 18 is inclined by 45° with respect to the XY plane in FIG. 1, the posture of the sample piece Q is controlled such that the upper end surface Qb of the sample piece Q separated and extracted from the original sample is rotated from the horizontal plane (XY plane in FIG. 1) to a plane perpendicular to the XY plane by rotating the needle 18 by 90°.

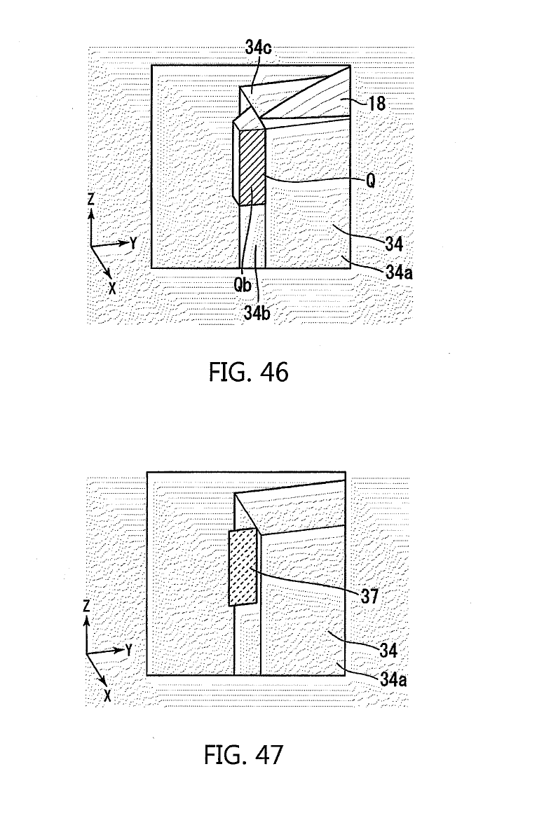

FIG. 46 is a diagram illustrating a state in which the sample piece Q fixed to the tip of the needle 18 has moved so as to be in contact with the columnar portion 34 of the sample piece holder P. One side surface 34a of the columnar portion 34 is a surface perpendicular to the irradiation direction of an electron beam when observed with a transmission electron microscope, and one side surface (end face) 34b is a surface parallel to the irradiation direction of the electron beam. One side surface (upper end surface 34c) of the columnar portion 34 is a surface perpendicular to the irradiation direction of a focused ion beam in FIG. 1, and is the top surface of the columnar portion 34.

In the present embodiment, the upper end surface Qb of the sample piece Q whose posture is controlled by the needle is moved so as to be parallel to and preferably so as to be flush with the side surface 34a of the columnar portion 34 of the sample piece holder P, and the cross-sectional surface of the sample piece Q is brought into surface contact with the sample piece holder. After it is confirmed that the sample piece is in contact with the sample piece holder, a deposition film is formed on the upper end surface 34c of the columnar portion 34, specifically at a portion where the sample piece and the sample piece holder are in contact with each other. That is, the deposition film is formed to straddle the sample piece and the sample piece holder.

FIG. 47 is a schematic diagram illustrating a state in which a planar sample piece 37 is manufactured by irradiating a sample piece Q fixed to a sample piece holder with a focused ion beam. The planar sample piece 37 disposed at a predetermined sample depth from the sample surface is manufactured through a process in which a distance from the upper end surface Qb of the sample piece Q to a position where the planar sample piece 37 is to be formed is obtained, and a focused ion beam is irradiated to the sample piece Q, so that the planar sample piece, which is parallel to the upper end surface Qb of the sample piece Q and has a predetermined thickness, is formed. By preparing such a planar sample piece, it is possible to be aware of the structure and composition distribution inside the sample in parallel with the surface of the sample.

The method for preparing the planar sample piece is not limited thereto. When the sample piece holder is mounted on a mechanism that can be tilted within a range of 0° to 90°, it is possible to prepare a planar sample piece by rotating the sample stage and tilting the sample holder without rotating a probe. Alternatively, when the needle is inclined at an angle within a range of 0° to 90° other than an angle of 45°, it is possible to prepare a planar sample piece by appropriately setting the inclination angle of the sample piece holder.

In this way, a planar sample piece can be prepared and a planar surface that is parallel to the surface of a sample at a predetermined depth from the sample surface can be observed with an electron microscope.

In the present embodiment, the sample piece extracted and separated was placed on one side surface of the columnar portion. Although fixing the sample piece to the upper end surface of the columnar portion can be considered, it is preferable that the sample piece is fixed to one side surface of the columnar portion for the following reason: when the sample piece undergoes a lamellation process using a focused ion beam, the focused ion beam hits the upper end surface of the columnar portion, and sputtering particles generated from the site adhere to a lamellate portion of the sample piece, which makes the formed planar sample piece unsuitable for microscopic observation.

Hereinafter, other embodiments will be described.

(a1) A charged particle beam apparatus that is a charged particle beam apparatus for automatically preparing a sample piece from a sample, the charged particle beam apparatus including at least:

a plurality of charged particle beam irradiation optical systems (beam irradiation optical systems), each irradiating a charged particle beam;

a sample stage configured to move with the sample placed thereon;

a sample piece transferring device having a needle to be connected to the sample piece to be separated and extracted from the sample and transporting the sample piece;

a holder fixing base configured to hold a sample piece holder having a columnar portion to which the sample piece is to be transferred;

a gas supply unit configured to supply a gas for formation of a deposition film in a state in which the charged particle beam is irradiated; and

a computer configured to measure an electric characteristic between the sample piece and the columnar portion and control at least the charged particle beam irradiation optical systems, the sample piece transferring device, and the gas supply unit such that the deposition film is formed to straddle the columnar portion and the sample piece that is stationed with a gap between the sample piece and the columnar portion until the measured electric characteristic reaches a predetermined electric characteristic value.

(a2) A charged particle beam apparatus that is a charged particle beam apparatus for automatically preparing a sample piece from a sample, the charged particle beam apparatus including at least:

a plurality of charged particle beam irradiation optical systems (beam irradiation optical systems), each irradiating a charged particle beam;

a sample stage that moves with the sample placed thereon;

a sample piece transferring device having a needle to be connected to the sample piece to be separated and extracted from the sample and transporting the sample piece;

a holder fixing base configured to a sample piece holder having a columnar portion to which the sample piece is to be transferred;

a gas supply unit configured to supply a gas for formation of a deposition film in a state in which the charged particle beam is irradiated; and

a computer configured to measure an electric characteristic between the sample piece and the columnar portion and control at least the charged particle beam irradiation optical systems, the sample piece transferring device, and the gas supply unit such that the deposition film is formed to straddle the columnar portion and the sample piece that is stationed with a gap between the columnar portion and the sample piece for a predetermined time.

(a3) A charged particle beam apparatus that is a charged particle beam apparatus for automatically preparing a sample piece from a sample, the charged particle beam apparatus including at least:

a focused ion beam irradiation optical systems (beam irradiation optical system) configured to irradiate a focused ion beam;

a sample stage that moves with the sample placed thereon;

a sample piece transferring device having a needle to be connected to the sample piece to be separated and extracted from the sample and transporting the sample piece;

a holder fixing base configured to hold a sample piece holder having a columnar portion to which the sample piece is to be transferred;

a gas supply unit configured to supply a gas for formation of a deposition film in a state in which the focused ion beam is irradiated; and

a computer configured to measure an electric characteristic between the sample piece and the columnar portion and control at least the focused ion beam irradiation optical system, the sample piece transferring device, and the gas supply unit such that the deposition film is formed to straddle the columnar portion and the sample piece that is stationed with a gap between the columnar portion and the sample piece until the measured electric characteristic reaches a predetermined electric characteristic value.

(a4) A charged particle beam apparatus that is a charged particle beam apparatus for automatically preparing a sample piece from a sample, the charged particle beam apparatus including at least:

a focused ion beam irradiation optical systems (beam irradiation optical system) configured to irradiate a focused ion beam;

a sample stage configured to move with the sample placed thereon;

a sample piece transferring device having a needle to be connected to the sample piece to be separated and extracted from the sample and transporting the sample piece;

a holder fixing base configured to hold a sample piece holder having a columnar portion to which the sample piece is to be transferred;

a gas supply unit configured to supply a gas for formation of a deposition film in a state in which the focused ion beam is irradiated; and

a computer configured to measure an electric characteristic between the sample piece and the columnar portion and control at least the focused ion beam irradiation optical system, the sample piece transferring device, and the gas supply unit such that the deposition film is formed to straddle the columnar portion and the sample piece that is stationed with a gap between the columnar portion and the sample piece for a predetermined time.

(a5) In the charged particle beam apparatus according to (a1) or (a2), the charged particle beam includes at least a focused ion beam and an electron beam.

(A6) In the charged particle beam apparatus according to any one of (a1) to (a4), the electrical characteristic is at least one of an electrical resistance, a current, and an electrical potential.

(a7) In the charged particle beam apparatus according to any one of (a1) to (a6), the computer moves the sample piece such that the gap between the sample piece and the columnar portion is reduced when the electrical characteristic does not reach a predetermined electrical characteristic value in a predetermined deposition film formation time and controls at least the beam irradiation optical system, the sample piece transferring device, and the gas supply unit such that the deposition film is formed to straddle the columnar portion and the sample piece that is stationed.

(a8) In the charged particle beam apparatus according to any one of (a1) to (a6), the computer controls at least the beam irradiation optical system and the gas supply unit such that formation of the deposition film is stopped when the electrical characteristic between the sample piece and the columnar portion satisfies a predetermined electrical characteristic value in a predetermined deposition film formation time.

(A9) In the charged particle beam apparatus according to (a1) or (a3), the gap has a size of 1 μm or less.

(A10) In the charged particle beam apparatus according to (a9), the gap has a size of 100 nm or more and 200 nm or less.

(b1) A charged particle beam apparatus that is a charged particle beam apparatus for automatically preparing a sample piece from a sample, the charged particle beam apparatus including:

a charged particle beam irradiation optical system configured to irradiate a charged particle beam;

a sample stage configured to move with the sample placed thereon;

a sample piece transferring device configured to hold and transport the sample piece separated and extracted from the sample;

a holder fixing base configured to hold a sample piece holder having a columnar portion to which the sample piece is to be transferred; and

a computer configured to create a template of the columnar portion based on an image of the columnar portion acquired by scanning the charged particle beam and to control the charged particle beam irradiation optical system and the sample piece transferring device with reference to position information obtained through template matching using the template such that the sample piece is transferred to the columnar portion.

(b2) In the charged particle beam apparatus described (b1), the sample piece holder includes a plurality of columnar portions spaced from each other as the columnar portion, and the computer creates templates of the respective columnar portions based on the images of the respective columnar portions.

(b3) In the charged particle beam apparatus described in (b2), the computer performs a determination process of determining whether or not a shape of a target columnar portion selected among the plurality of columnar portions matches a predetermined shape that is previously registered, through template matching using the templates of the respective columnar portions,

wherein when the shape of the target columnar portion does not match the predetermined shape, the computer sets another columnar portion as a new target columnar portion and performs the determination process with respect to the new target columnar portion, and

wherein when the shape of the target columnar portion matches the predetermined shape, the computer controls movement of the charged particle beam irradiation optical system and either the sample piece transferring device or the sample stage such that the sample piece is transferred the target columnar portion.

(b4) In the charged particle beam apparatus according to (b2) or (b3), when controlling movement of the sample stage such that the target columnar portion among the plurality of columnar portions is disposed at a predetermined position, the computer initializes a position of the sample stage when it is determined that the target columnar portion is not disposed at the predetermined position.

(b5) In the charged particle beam apparatus described in (b4), when controlling the movement of the sample stage such that the target columnar portion among the plurality of columnar portions is disposed at the predetermined position, the computer performs a shape determination process of determining whether the shape of the target columnar shape is normal or abnormal after the sample stage is moved,

wherein when the shape of the target columnar shape is abnormal, the computer sets another columnar portion as a new target columnar portion, controls the movement of the sample stage such that the new target columnar portion is disposed at the predetermined position, and performs the shape determination process.

(b6) In the charged particle beam apparatus according to any one of (b1) to (b5), the computer creates a template of the columnar portions prior to separating and extracting the sample piece from the sample.

(b7) In the charged particle beam apparatus described in (b3),

the computer records images of the respective columnar portions of the plurality of columnar portion, edge information extracted from each image, or design information of each of the plurality of columnar portions as the templates, and determines whether or not the shape of the target columnar portion matches the predetermined shape in accordance with scores of template matching using the templates.

(b8) In the charged particle beam apparatus according to any one of (b1) to (b7), the computer records an image acquired by irradiating, with the charged particle beam, the columnar portion to which the sample piece is transferred, and position information of the columnar portion to which the sample piece is transferred.

(c1) A charged particle beam apparatus that is a charged particle beam apparatus for automatically preparing a sample piece from a sample, the charged particle beam apparatus including:

a charged particle beam irradiation optical system configured to irradiate a charged particle beam;

a sample stage configured to move with the sample placed thereon;

a sample piece transferring device configured to hold and transport the sample piece separated and extracted from the sample;

a holder fixing base configured to hold a sample piece holder having a columnar portion to which the sample piece is to be transferred;

a gas supply unit configured to supply a gas for formation of a deposition film in a state in which the charged particle beam is irradiated;

a computer configured to control the charged particle beam irradiation optical system and the sample piece transferring device such that the charged particle beam is irradiated to the deposition film attached to the sample piece transferring device after the sample piece transferring device is separated from the sample piece.

(c2) In the charged particle beam apparatus described in (c1), the sample piece transferring device repeats holding and transporting the sample piece separated and extracted from the sample a plurality of times.

(c3) In the charged particle beam apparatus according to (c1) or (c2), the computer repeatedly controls the particle beam irradiation optical system and the sample piece transferring device such that the charged particle beam is irradiated to the deposition film attached to the sample piece transferring device at predetermined timing including at least timing at which the sample piece transferring device is separated from the sample piece.

(c4) In the charged particle beam apparatus according to any one of (c1) to (c3), the computer initializes a position of the sample piece transferring device when the sample piece transferring device is not disposed at a predetermined position, at the time of controlling the sample piece transferring device such that the sample piece transferring device separated from the sample piece is disposed at the predetermined position.

(c5) In the charged particle beam apparatus described in (c4), when the sample piece transferring device is not disposed at the predetermined position even though movement of the sample piece transferring device is controlled after the position of the sample piece transferring device is initialized, the computer stops controlling the sample piece transferring device.

(c6) In the charged particle beam apparatus according to any one of (c1) to (c5), the computer creates a template of the sample piece transferring device based on an image acquired by irradiating the sample piece transferring device with the charged particle beam before the sample piece transferring device is connected to the sample piece, and controls the charged particle beam irradiation optical system and the sample piece transferring device based on outline information obtained through template matching using the template such that the charged particle beam is irradiated to the deposition film attached to the sample piece transferring device.

(c7) In the charged particle beam apparatus according to (c6), a display device that displays the outline information thereon is further included.

(c8) In the charged particle beam apparatus according to any one of (c1) to (c7), the computer performs eccentricity correction when the sample piece transferring device is rotated around a central axis so that the sample piece transferring device has a predetermined posture.

(c9) In the charged particle beam apparatus according to any one of (c1) to (c8), the sample piece transferring device includes a needle or tweezers connected to the sample piece.

In the embodiments described above, the computer 22 also includes a software function unit or a hardware function unit such as an LSI.

Although as the needle 18, a needle-shaped member with a sharp tip has been described in the above-described embodiments, the needle 18 may have a flat chisel shape having a flat tip.

The present invention can be applied to a case where at least the sample piece Q to be extracted is formed of carbon. According to the present invention, it is possible to move an object to a desired position using a template and position coordinates of a needle tip. In other words, when the extracted sample piece Q is transferred to the sample holder P in a state of being fixed to the tip of the needle 18, the needle 18 to which the sample piece Q is fixed can be controlled such that the sample piece Q approaches the sample piece holder P and stops at a position spaced from the sample piece holder P, by using the coordinates of the actual tip (the tip coordinates of the sample piece) acquired from a secondary electron image formed by an irradiation target with a charged particle beam, and the template of the needle 18 generated from an absorption current image of the needle 18 to which the sample piece Q is attached.

In addition, the present invention can be applied to other apparatuses. For example, in a charged particle beam apparatus that measures an electric characteristic of a minute portion by bringing a probe into contact with the minute portion, particularly in an apparatus equipped with a metal probe inside a sample chamber of a scanning electron microscope using an electron as a charged particle beam, and in a charged particle beam apparatus that measures an electrical characteristic using a tungsten probe provided with a carbon nanotube at the tip thereof to be brought into contact with a conductive portion of a fine region, it is difficult to recognize the tip of the tungsten probe in a conventional secondary electron image due to the background which may include a wire pattern. For this reason, an absorption current image is used to make it easier to recognize a tungsten probe. However, with the absorption current image, the tip of a carbon nanotube cannot be recognized and thus the carbon nanotube cannot be brought into contact with a critical measurement point. Therefore, in the present invention, the coordinates of the actual tip of the needle 18 are specified by using a secondary electron image, and the template is created by using an absorption current image. Thereby, the probe provided with the carbon nanotube can be moved to and brought into contact with a specific measurement position.

In addition, the sample piece Q prepared with the charged particle beam apparatus 10 according to the present invention may be introduced into another focused ion beam apparatus and carefully further processed thereto to have a thickness suitable for transmission electron microscopic analysis by an operator. Thus, when the charged particle beam apparatus 10 according to the present invention and a focused ion beam apparatus are used in combination, it is possible to fix a plurality of sample pieces Q to a sample piece holder P unattended during the night time, and the sample pieces Q can be finished as ultrathin specimens for transmission electron microscopic observation by a careful operator during the day time. Therefore, mental and physical burdens of an operator can be greatly reduced as compared with the related art in which a series of operations from sample extraction to lamellation are performed with one apparatus while relying on an operator. Therefore, work efficiency can be improved.

In addition, the above embodiments are presented for illustrative purposes, and are not intended to limit the scope of the present invention. These novel embodiments can be implemented in various other forms, and omissions, substitutions, and changes thereof are possible without departing from the spirit of the invention. These embodiments and modifications thereof are included in the scope or gist of the invention, and are included in the invention described in the following claims and the equivalent scope thereof.

For example, in the charged particle beam apparatus 10 according to the present invention, although the needle 18 has been described as a means for extracting the sample piece Q, the present invention is not limited thereto. The sample piece extracting device may be tweezers that can be finely controlled. When tweezers are used as the sample piece extracting device, the sample piece Q can be extracted without requiring a deposition process and there is no fear of wearing of the tip or the like. Even in the case of using the needle 18, a connection method of connecting the needle with the sample piece Q is not limited to a deposition process. The connection of the needle with the sample piece Q can be performed in a manner that the needle 18 imparted with electrostatic force is brought into contact with the sample piece Q and thus the sample piece Q is adsorbed onto the needle due to electrostatic force.

What is claimed is:

1. A charged particle beam apparatus for automatically preparing a sample piece from a sample, the charged particle beam apparatus comprising:
a charged particle beam irradiation optical system configured to irradiate a charged particle beam;
a sample stage configured to move with the sample placed thereon;
a sample piece transferring device configured to hold and transport the sample piece separated and extracted from the sample;
a holder fixing base configured to hold a sample piece holder to which the sample piece is to be transferred; and
a computer configured to perform control of destroying the sample piece held by the sample piece transferring device when an abnormality occurs after the sample piece transferring device holds the sample piece.

2. The charged particle beam apparatus according to claim 1, wherein the computer destroys the sample piece by irradiating the sample piece held by the sample piece transferring device with the charged particle beam.

3. The charged particle beam apparatus according to claim 2, wherein the sample piece transferring device includes a needle configured to hold and transport the sample piece separated and extracted from the sample and a needle driving mechanism configured to drive the needle; and
the computer sets a plurality of limited fields of view, limiting a region to which the charged particle beam is irradiated when destroying the sample piece, and controls the charged particle beam irradiation optical system and the needle driving mechanism such that the charged particle beam is irradiated while the limited fields of view are switched in order from a limited field of view farther from the needle to a limited field of view closer to the needle.

4. The charged particle beam apparatus according to claim 3, wherein the computer sets, among the plurality of limited fields of view, a limited field of view closer to the needle relatively smaller than a limited field of view father from the needle; and
the computer sets intensity of the charged particle beam for, among the plurality of limited fields of view, a limited field of view closer to the needle relatively weaker than intensity of the charged particle beam for a limited field of view farther to the needle.

5. The charged particle beam apparatus according to claim 4, wherein the computer sets the plurality of limited fields of view such that the needle is not included, based on a reference position of the sample piece acquired from an image formed by irradiating the charged particle beam to the sample piece and on a size of the sample piece acquired from known information or the image in advance.

6. The charged particle beam apparatus according to claim 5, wherein the computer controls the needle driving mechanism such that a reference position of the sample piece acquired from an image obtained by irradiating the sample piece with the charged particle beam when destroying the sample piece coincides with a center of a field of view of the charged particle beam.

7. The charged particle beam apparatus according to claim 6, wherein the computer sets a position of an edge extracted at an opposite end from an end connected to the needle when viewed from a center of the sample piece as a reference position of the sample piece.

8. The charged particle beam apparatus according to claim 1, wherein the sample piece transferring device includes a needle configured to hold and transport the sample piece separated and extracted from the sample and a needle driving mechanism configured to drive the needle; and
the computer controls the needle driving mechanism such that the sample piece is destroyed by separating the sample piece from the needle by colliding the sample piece held by the needle with an obstacle.
